(19) United States
(12) Patent Application Publication
(10) Pub. No.: US 2025/0089535 A1
(43) Pub. Date: Mar. 13, 2025

(54) DISPLAY DEVICE

(71) Applicant: LG DISPLAY CO., LTD., Seoul (KR)

(72) Inventors: SeongYong UHM, Paju-si (KR); MinHo OH, Paju-si (KR)

(73) Assignee: LG DISPLAY CO., LTD., Seoul (KR)

(21) Appl. No.: 18/826,996

(22) Filed: Sep. 6, 2024

(30) Foreign Application Priority Data
Sep. 12, 2023 (KR) 10-2023-0121188

(51) Int. Cl. H10K 59/80; H10K 59/122; H10K 59/131; H10K 59/40; H10K 102/00

(52) U.S. Cl. CPC H10K 59/873; H10K 59/122; H10K 59/131; H10K 59/40; H10K 2102/351

(57) ABSTRACT

A display device includes a substrate including a display area on which a plurality of subpixels are arranged, a non-display area located outside the display area and including a pad area, and a groove, an insulating layer disposed on the substrate, a bank disposed on the insulating layer and having a plurality of openings, and a barrier layer extending from an upper portion of the bank to the groove.

### CROSS-REFERENCE TO RELATED APPLICATION

This application claims the priority of Korean Patent Application No. 10-2023-0121188, filed on Sep. 12, 2023, which is hereby incorporated by reference in its entirety.

### BACKGROUND

### Field of the Disclosure

The present disclosure relates to a display device.

### Description of the Background

A display panel of a display device may include a display area where an image is displayed and a non-display area where the image is not displayed. There may be disposed various structures, circuits, and lines in the non-display area (also referred to as “bezel”) of the display panel. Accordingly, there may not be easy to reduce the bezel of the display panel.

### SUMMARY

Accordingly, the present disclosure is to provide a display device that substantially obviates one or more of problems due to limitations and disadvantages described above.

More specifically, the present disclosure is to provide a display device having an extremely narrow bezel structure.

The present disclosure is also to provide a display device capable of implementing an extremely narrow bezel while preventing overflow of an organic layer included in an encapsulation layer to prevent moisture and oxygen from penetrating.

The present disclosure is also to provide a display device capable of effectively preventing moisture penetration while realizing an extremely narrow bezel.

The present disclosure is also to provide a display device including a gate-in-panel circuit structure which enables an extremely narrow bezel.

Further, the present disclosure is to provide a display device with a touch routing structure which enables an extremely narrow bezel.

Additional features and advantages of the disclosure will be set forth in the description which follows and in part will be apparent from the description, or may be learned by practice of the disclosure. Other advantages of the present disclosure will be realized and attained by the structure particularly pointed out in the written description and claims hereof as well as the appended drawings.

To achieve these and other advantages and in accordance with the present disclosure, as embodied and broadly described, a display device includes a substrate including a display area on which a plurality of subpixels are arranged, a non-display area located outside the display area and including a pad area, and a groove, an insulating layer disposed on the substrate, a bank disposed on the insulating layer and having a plurality of openings, and a barrier layer extending from an upper portion of the bank to the groove.

In the display device according to aspects of the present disclosure, the groove may be formed in the substrate in the form of a trench along a second non-display area, a third non-display area, and a fourth non-display area. However, in at least a portion of a first non-display area, the groove may not be formed in the substrate.

In the display device according to aspects of the present disclosure, a first common intermediate layer, a second common intermediate layer, and a cathode may be disposed on an inner side of the barrier layer, and may not be disposed on an upper portion of the barrier layer.

The display device according to aspects of the present disclosure may further include a first protective film disposed on the cathode, a first foreign matter protective layer disposed on the first protective film, and a second protective film disposed on the first foreign matter protective layer.

In the display device according to aspects of the present disclosure, the first protective film may include a first material protective film including a first material, and a second material protective film including a second material different from the first material.

The display device according to aspects of the present disclosure may further include a second foreign matter protective layer disposed on the second protective film, and a buffer layer disposed on the second foreign matter protective layer.

The display device according to aspects of the present disclosure may further include a gate driving circuit including a plurality of gate-in-panel circuits for supplying gate signals to a plurality of subpixels.

In the display device according to aspects of the present disclosure, the gate driving circuit may be disposed within the display area. Each of a plurality of gate driving circuit areas may be disposed between two adjacent pixel areas among a plurality of pixel areas.

The display device according to aspects of the present disclosure may further include a plurality of sensor electrodes disposed on the buffer layer, and a plurality of touch routing lines corresponding to the plurality of sensor electrodes.

In the display device according to aspects of the present disclosure, the non-display area may include a first non-display area located outside the display area in a first direction and including the pad area, a second display area located outside the display area in a second direction different from the first direction, a third non-display area located outside the display area in a direction opposite to the first direction, and a fourth non-display area located outside the display area in a direction opposite to the second direction.

In the display device according to aspects of the present disclosure, the plurality of touch routing lines may be not disposed in the second non-display area, the third non-display area, and the fourth non-display area. In addition, at least a portion of the plurality of touch routing lines may be disposed to extend across the display area to the pad area within the first non-display area.

In the display device according to aspects of the present disclosure, the plurality of touch routing lines may extend along outer sides of the second foreign matter protective layer, the first foreign matter protective layer, and the insulating layer, and may be electrically connected to a touch pad disposed in the pad area.

The display device according to aspects of the present disclosure may include a substrate including a display area on which a plurality of subpixels are disposed, and a non-display area located outside the display area and including a pad area, an insulating layer disposed on the substrate, and a bank disposed on the insulating layer and having a plurality of openings.

The non-display area may include a first non-display area located outside the display area in a first direction and including the pad area, a second display area located outside the display area in a second direction different from the first direction, a third non-display area located outside the display area in a direction opposite to the first direction, and a fourth non-display area located outside the display area in a direction opposite to the second direction.

The display device according to aspects of the present disclosure may further include a groove which is not formed in at least a portion of the first non-display area including the pad area among the non-display areas, and is formed in the substrate in the form of a trench in remaining non-display area excluding the first non-display area among the non-display area.

According to aspects of the present disclosure, there may provide a display device with an extremely narrow bezel structure.

According to aspects of the present disclosure, there may provide a display device capable of implementing an extremely narrow bezel while preventing overflow of an organic layer included in an encapsulation layer to prevent moisture and oxygen from penetrating.

According to aspects of the present disclosure, there may provide a display device capable of effectively preventing moisture penetration while realizing an extremely narrow bezel.

According to aspects of the present disclosure, there may provide a display device including a gate-in-panel circuit structure which enables an extremely narrow bezel.

According to aspects of the present disclosure, there may provide a display device with a touch routing structure which enables an extremely narrow bezel.

According to aspects of the present disclosure, it is possible to reduce the weight of a display device by having an extremely narrow bezel structure.

It is to be understood that both the foregoing general description and the following detailed description are exemplary and explanatory and are intended to provide further explanation of the disclosure as claimed.

### BRIEF DESCRIPTION OF THE DRAWINGS

The accompanying drawings, which are included to provide a further understanding of the disclosure and are incorporated in and constitute a part of the disclosure, illustrate aspects of the disclosure and together with the description serve to explain the principle of the disclosure.

In the drawings:

FIG. 1 is a system configuration diagram of a display device according to aspects of the present disclosure.

FIG. 2 illustrates a display panel according to aspects of the present disclosure.

FIG. 3 illustrates a substrate of a display panel according to aspects of the present disclosure.

FIG. 4 is a cross-sectional view of a display panel according to aspects of the present disclosure.

FIGS. 5 to 14 illustrate a manufacturing process of a display panel according to aspects of the present disclosure.

FIG. 15 is another cross-sectional view of a display panel according to aspects of the present disclosure.

FIG. 16 is a plan view of a display panel according to aspects of the present disclosure.

FIG. 17 briefly illustrates a gate-in-panel circuit according to aspects of the present disclosure.

FIG. 18 is another cross-sectional view of a display panel according to aspects of the present disclosure.

FIG. 19 illustrates a touch sensor included in a display panel according to aspects of the present disclosure.

FIG. 20 is another cross-sectional view of a display panel according to aspects of the present disclosure.

FIG. 21 is another cross-sectional view of a display panel according to aspects of the present disclosure.

FIGS. 22A to 22D illustrate examples of a groove formed in a substrate of a display panel according to aspects of the present disclosure.

### DETAILED DESCRIPTION

Hereinafter, aspects of the disclosure are described in detail with reference to the accompanying drawings. In assigning reference numerals to components of each drawing, the same components may be assigned the same numerals even when they are shown on different drawings. When determined to make the subject matter of the disclosure unclear, the detailed of the known art or functions may be skipped. As used herein, when a component “includes,” “has,” or “is composed of” another component, the component may add other components unless the component “only” includes, has, or is composed of” the other component. As used herein, the singular forms “a”, “an” and “the” are intended to include the plural forms as well, unless the context clearly indicates otherwise.

Such denotations as “first,” “second,” “A,” “B,” “(a),” and “(b),” may be used in describing the components of the disclosure. These denotations are provided merely to distinguish a component from another, and the essence, order, or number of the components are not limited by the denotations.

In describing the positional relationship between components, when two or more components are described as “connected”, “coupled” or “linked”, the two or more components may be directly “connected”, “coupled” or “linked” “, or another component may intervene. Here, the other component may be included in one or more of the two or more components that are “connected”, “coupled” or “linked” to each other.

When such terms as, e.g., “after”, “next to”, “after”, and “before”, are used to describe the temporal flow relationship related to components, operation methods, and fabricating methods, it may include a non-continuous relationship unless the term “immediately” or “directly” is used.

When a component is designated with a value or its corresponding information (e.g., level), the value or the corresponding information may be interpreted as including a tolerance that may arise due to various factors (e.g., process factors, internal or external impacts, or noise).

Hereinafter, various aspects of the disclosure are described in detail with reference to the accompanying drawings.

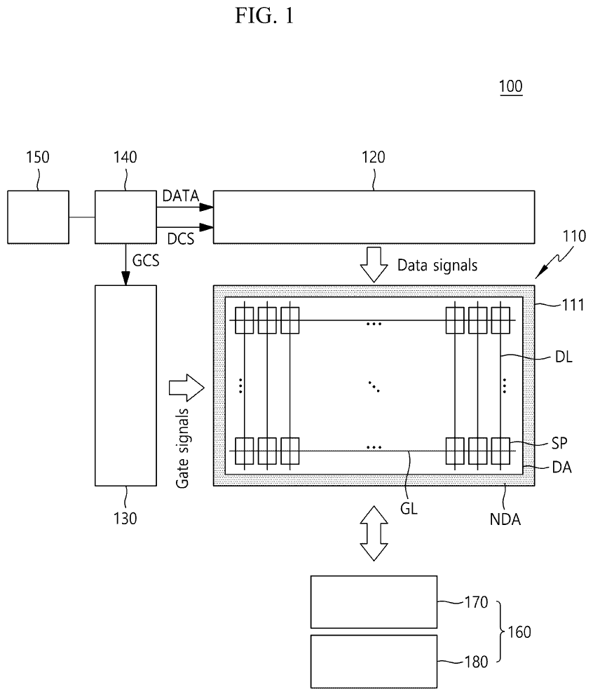

FIG. 1 is a system configuration diagram of a display device 100 according to aspects of the present disclosure.

Referring to FIG. 1, a display device 100 according to aspects of the present disclosure may include a display panel 110 and a display driving circuit as components for displaying an image. The display driving circuit is a circuit for driving the display panel 110, and may include a data driving circuit 120, a gate driving circuit 130, and a display controller 140.

The display panel 110 may include a substrate 111 and a plurality of subpixels SP disposed on the substrate 111.

The substrate 111 of the display panel 110 may include a display area DA for displaying an image and a non-display area NDA located outside the display area DA.

A plurality of subpixels SP for image display may be disposed in the display area DA, and the non-display area NDA may include a pad area PA located in the first direction from the display area DA.

In a display panel 110 according to aspects of the present disclosure, the non-display area NDA may be very small. In this specification, the non-display area NDA may be also referred to as a “bezel.”

For example, the non-display area NDA may include a first non-display area located outside the display area DA in a first direction, a second non-display area located outside the display area DA in a second direction different from the first direction, a third non-display area located outside the display area DA in the opposite direction to the first direction, and a fourth non-display area located outside the display area DA in the direction opposite to the second direction. One or both of the first to fourth non-display areas may include a pad area to which the data driving circuit 120 is connected or bonded. Among the first to fourth non-display areas, two or three without the pad area may be very small in size. For example, the first non-display area may include a pad area, and the sizes of the second non-display area, third non-display area, and fourth non-display area may be very small.

For another example, a boundary area between the display area DA and the non-display area NDA may be bent so that the non-display area NDA may be located below the display area. In this case, when the user looks at the display device 100 from the front, there may be little or no non-display area NDA visible to the user. The display device 100 may appear bezel-less to the user.

Various types of signal lines for driving a plurality of subpixels SP may be disposed on the substrate 111 of the display panel 110.

The display device 100 according to aspects of the present disclosure may be a liquid crystal display device or the like, or may be a self-luminous display device in which the display panel 110 emits light by itself. When the display device 100 according to aspects of the present disclosure is a self-luminous display device, each of the plurality of subpixels SP may include a light emitting device.

For example, the display device 100 according to aspects of the present disclosure may be an organic light emitting display device in which a light emitting device is implemented as an organic light emitting diode (OLED). For another example, the display device 100 according to aspects of the present disclosure may be an inorganic light emitting display device in which the light emitting device is implemented as an inorganic-based light emitting diode. For another example, the display device 100 according to aspects of the present disclosure may be a quantum dot display device in which a light emitting device is implemented with quantum dots, which are semiconductor crystals emitting light by itself.

The structure of each of the plurality of subpixels SP may vary depending on the type of the display device 100. For example, if the display device 100 is a self-luminous display device with the subpixel SP emitting light by itself, each subpixel SP may include a self-luminous light emitting device, one or more transistors, and one or more capacitors.

For example, various types of signal lines may include a plurality of data lines DL supplying data signals (also called data voltages or image signals) and a plurality of gate lines GL for transmitting gate signals (also called scan signals).

For example, the plurality of data lines DL and the plurality of gate lines GL may cross each other. Each of the plurality of data lines DL may be arranged to extend in a first direction. Each of the plurality of gate lines GL may be arranged to extend in a second direction. Here, the first direction may be a column direction and the second direction may be a row direction. Alternatively, the first direction may be a row direction and the second direction may be a column direction. Hereinafter, for convenience of explanation, it will exemplify a case in which each of the plurality of data lines DL is arranged in a column direction, and each of the plurality of gate lines GL is arranged in a row direction.

The data driving circuit 120 is a circuit for driving a plurality of data lines DL, and may output data signals to the plurality of data lines DL.

The data driving circuit 120 may receive image data in digital form from the display controller 140 and convert the received image data into analog data signals to output to a plurality of data lines DL.

For example, the data driving circuit 120 may be connected to the display panel 110 using a tape automated bonding (TAB) method, or may be connected to the bonding pad of the display panel 110 using a chip-on-glass (COG) or chip-on-panel (COP) method, or may be implemented using a chip-on-film (COF) method and connected to the display panel 110.

The data driving circuit 120 may be connected to one side (e.g., the upper or lower side) of the display panel 110. Depending on the driving method, panel design method, etc., the data driving circuit 120 may be connected to both sides (e.g., upper and lower sides) of the display panel 110, or may be connected to two or more of the four sides of the display panel 110.

The data driving circuit 120 may be connected to the outside of the display area DA of the display panel 110, but alternatively, it may be disposed in the display area DA of the display panel 110.

The gate driving circuit 130 is a circuit for driving a plurality of gate lines GL, and may output gate signals to the plurality of gate lines GL.

The gate driving circuit 130 may receive a first gate voltage corresponding to the turn-on level voltage and a second gate voltage corresponding to the turn-off level voltage along with various gate driving control signals GCS, and may generate gate signals and supply the generated gate signals to the plurality of gate lines GL.

In the display device 100 according to aspects of the present disclosure, the gate driving circuit 130 may be built into the display panel 110 as a gate-in-panel (GIP) type. If the gate driving circuit 130 is a gate-in-panel type, the gate driving circuit 130 may be formed on a substrate of the display panel 110 during the manufacturing process of the display panel 110.

In the display device 100 according to aspects of the present disclosure, the gate driving circuit 130 may be disposed in the display area DA of the display panel 110. For example, the gate driving circuit 130 may be disposed in a first partial area within the display area DA (e.g., a left area or a right area within the display area DA). For another example, the gate driving circuit 130 may be disposed in a first partial area within the display area DA (e.g., a left area or a right area within the display area DA) and a second partial area (e.g., a right area or a left area within the display area DA). As another example, the gate driving circuit 130 may be distributed and disposed throughout the display area DA.

In the present disclosure, a gate driving circuit 130 built into the display panel 110 as a gate-in-panel type may be referred to as a “gate-in-panel circuit.”

The display controller 140 may be a device for controlling the data driving circuit 120 and the gate driving circuit 130, and may control the driving timing for the plurality of data lines DL and the driving timing of the plurality of gate lines GL.

The display controller 140 may supply a data driving control signal DCS to the data driving circuit 120 to control the data driving circuit 120, and may supply a gate driving control signal GCS to the gate driving circuit 130 to control the gate driving circuit 130.

The display controller 140 may receive input image data from a host system 150 and supply image data DATA to the data driving circuit 120 based on the input image data.

The display controller 140 may be implemented as a separate component from the data driving circuit 120, or may be integrated with the data driving circuit 120 and implemented as an integrated circuit.

The display controller 140 may be a timing controller used in typical display technology, or may be a control device capable of further performing other control functions including a timing controller, or may be a control device different from the timing controller, or may be a control device other than a timing controller, or may be a circuit within the control device. The display controller 140 may be implemented with various circuits or electronic components, such as an integrated circuit (IC), a field programmable gate array (FPGA), an application specific integrated circuit (ASIC), or Processor.

The display controller 140 may be mounted on a printed circuit board, a flexible printed circuit, etc., and may be electrically connected to the data driving circuit 120 and the gate driving circuit 130 through a printed circuit board, a flexible printed circuit.

The display controller 140 may transmit and receive signals with the data driving circuit 120 according to one or more predetermined interfaces. For example, the interface may include a low voltage differential signaling (LVDS) interface, an embedded clock point-point interface (EPI) interface, or a serial peripheral interface (SPI).

To provide not only an image display function but also a touch sensing function, the display device 100 according to aspects of the present disclosure may include a touch sensor and a touch sensing circuit 160 for detecting an occurrence of a touch by a touch object such as a finger and pen, or detection a touch position by sensing the touch sensor.

The touch sensing circuit 160 may include a touch driving circuit 170 for driving and sensing a touch sensor to generate and output touch sensing data, and a touch controller 180 for detecting the occurrence of a touch or detecting the touch position using touch sensing data.

A touch sensor may include a plurality of touch electrodes. The touch sensor may further include a plurality of touch lines to electrically connect a plurality of touch electrodes and the touch driving circuit.

The touch sensor may exist outside the display panel 110 in the form of a touch panel or may exist inside the display panel 110. If the touch sensor exists outside the display panel 110 in the form of a touch panel, the touch sensor may be referred to as an external type. If the touch sensor is an external type, the touch panel and the display panel 110 may be manufactured separately and combined during the assembly process. The external touch panel may include a touch panel substrate and a plurality of touch electrodes on the touch panel substrate.

If the touch sensor exists inside the display panel 110, the touch sensor may be formed on the substrate along with signal lines and electrodes related to display driving during the manufacturing process of the display panel 110.

The touch driving circuit 170 may supply a touch driving signal to at least one of the plurality of touch electrodes and generate touch sensing data by sensing at least one of the plurality of touch electrodes.

The touch sensing circuit 160 may perform touch sensing using a self-capacitance sensing method or a mutual-capacitance sensing method.

If the touch sensing circuit 160 performs touch sensing using a self-capacitance sensing method, the touch sensing circuit may perform touch sensing based on the capacitance between each touch electrode and a touch object (e.g., finger, pen, etc.). According to the self-capacitance sensing method, each of the plurality of touch electrodes may serve as a driving touch electrode and a sensing touch electrode. The touch driving circuit 260 may drive all or part of the plurality of touch electrodes and sense all or part of the plurality of touch electrodes.

If the touch sensing circuit 160 performs touch sensing using the mutual-capacitance sensing method, the touch sensing circuit may perform touch sensing based on the capacitance between touch electrodes. According to the mutual-capacitance sensing method, the plurality of touch electrodes may be divided into driving touch electrodes and sensing touch electrodes. The touch driving circuit may drive driving touch electrodes and sense sensing touch electrodes.

The touch driving circuit 170 and the touch controller 180 included in the touch sensing circuit 160 may be implemented as separate devices or as one device. Additionally, the touch driving circuit 170 and the data driving circuit 120 may be implemented as separate devices or as one device.

The display device 100 may further include a power supply circuit which supplies various types of power to the display driving circuit and/or the touch sensing circuit 160.

The display device 100 according to aspects of the present disclosure may be a mobile terminal such as a smart phone or tablet, or a monitor or television of various sizes, but is not limited thereto, and may be a display of various types and sizes capable of displaying information or images.

The display device 100 according to aspects of the present disclosure may further include an electronic device such as a camera (e.g., image sensor) and a detection sensor. For example, the detection sensor may be a sensor for detecting an object or a human body by receiving light such as infrared, ultrasonic, or ultraviolet rays.

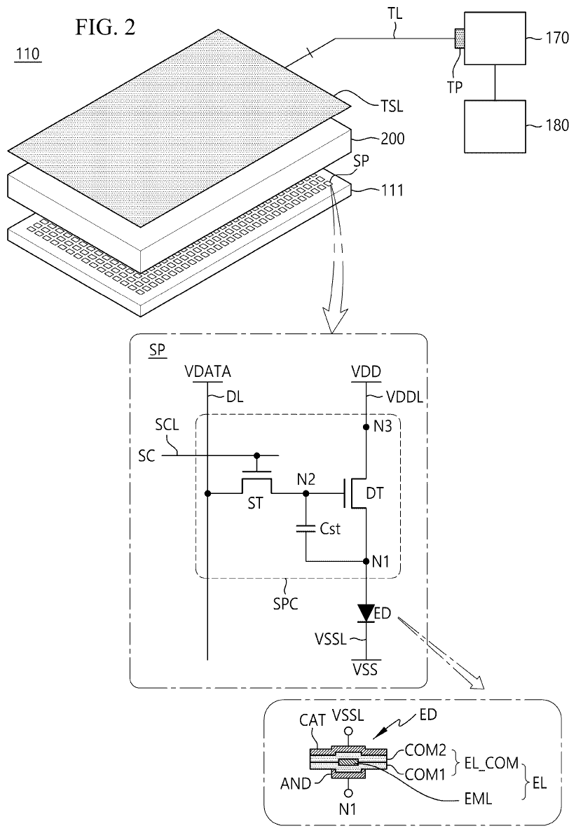

FIG. 2 illustrates a display panel 110 according to aspects of the present disclosure.

Referring to FIG. 2, the display panel 110 may include a substrate 111 disposed in a plurality of subpixels SP and an encapsulation layer 200 on the substrate 111. Here, the encapsulation layer 200 may also be referred to as an encapsulation substrate or an encapsulation portion.

Referring to FIG. 2, when the display device 100 according to aspects of the present disclosure is a self-luminous display device, each of the plurality of subpixels SP may include a light emitting device ED and a subpixel circuit SPC for driving the light emitting device ED.

Referring to FIG. 2, the subpixel circuit SPC may include a plurality of pixel driving transistors and at least one capacitor for driving the light emitting device ED. In the present disclosure, the subpixel circuit SPC may drive the light emitting device ED by supplying a driving current to the light emitting device ED at a predetermined timing. The light emitting device ED may be driven by a driving current and emit light.

The plurality of pixel driving transistors may include a driving transistor DT for driving the light emitting device ED, and a scan transistor ST which is turned on or off depending on the scan signal SC.

The driving transistor DT may supply driving current to the light emitting device ED.

The scan transistor ST may be configured to control the electrical state of a corresponding node in the subpixel circuit SPC or to control the state or operation of the driving transistor DT.

At least one capacitor may include a storage capacitor Cst to maintain a constant voltage during the frame.

To drive the subpixel SP, a data signal VDATA which is an image signal, and a scan signal SC which is a gate signal may be applied to the subpixel SP. In addition, a common pixel driving voltage including a first common driving voltage VDD and a second common driving voltage VSS may be applied to the subpixel SP to drive the subpixel SP.

The light emitting device ED may include an anode AND, an intermediate layer EL, and a cathode CAT. The intermediate layer EL may be located between the anode AND and the cathode CAT.

In the case that the light emitting device ED is an organic light emitting device, the intermediate layer EL may include an emission layer EML, a first common intermediate layer COM1 between the anode AND and the emission layer EML, and a second common intermediate layer COM2 between the emission layer EML and the cathode CAT. The first common intermediate layer COM1 and the second common intermediate layer COM2 may be collectively referred to as the common intermediate layer EL_COM.

The emission layer EML may be disposed for each subpixel SP, and the common intermediate layer EL_COM may be commonly disposed across a plurality of subpixels SP.

The emission EML may be disposed in each light emission area, and the common intermediate layer EL_COM may be commonly disposed across a plurality of emission areas and a non-emission area.

For example, the first common intermediate layer COM1 of the common intermediate layer EL_COM may include a hole injection layer HIL and a hole transport layer HTL. The second common intermediate layer COM2 the common intermediate layer EL_COM may include an electron transport layer ETL and an electron injection layer EIL.

The hole injection layer may inject holes from the anode AND to the hole transport layer, the hole transport layer may transport holes to the emission EML, the electron injection layer may inject electrons from the cathode CAT to the electron transport layer, and the electron transport layer may transport electrons to the emission layer EML.

For example, the cathode CAT may be electrically connected to a second common driving voltage line VSSL. A second common driving voltage VSS, which is a type of common pixel driving voltage, may be applied to the cathode CAT through the second common driving voltage line VSSL. The anode AND may be directly or indirectly (e.g., through another transistor) and electrically connected to a first node N1 of the driving transistor DT of each subpixel SP. In the present disclosure, the “second common driving voltage” VSS may also be referred to as a “base voltage” VSS, and the “second common driving voltage line” VSSL may also be referred to as a “base voltage line” VSSL.

For example, the anode AND may be a pixel electrode disposed in each subpixel SP, and the cathode CAT may be a common electrode commonly disposed in a plurality of subpixels SP. For another example, the cathode CAT may be a pixel electrode disposed in each subpixel SP, and the anode AND may be a common electrode commonly disposed in a plurality of subpixels SP. Hereinafter, for convenience of explanation, it is assumed that the anode AND is a pixel electrode and the cathode CAT is a common electrode.

Each light emitting device ED may be composed of overlapping parts of the anode AND PE, the intermediate layer EL and the cathode CAT. A predetermined emission area may be formed by each light emitting device ED. For example, the emission area of each light emitting device ED may include an area where the cathode AND, the intermediate layer EL and the cathode CAT overlap.

For example, the light emitting device ED may be an organic light emitting diode (OLED), an inorganic light emitting diode, or a quantum dot light emitting device. For example, in the case that the light emitting device ED is an organic light emitting diode OLED, the intermediate layer EL in the light emitting device ED may include an organic intermediate layer EL containing an organic material.

The driving transistor DT may be a driving transistor for supplying driving current to the light emitting device ED. The driving transistor DT may be connected between a first common driving voltage line VDDL and the light emitting device ED.

The driving transistor DT may include a first node N1, a second node N2, and a third node N3. The first node N1 may be electrically connected to the light emitting device ED, the data signal VDATA may be applied to the second node N2, and the first common driving voltage VDD may be applied to the third node N3 from the first common driving voltage line VDDL.

In the driving transistor DT, the second node N2 may be a gate node, the first node N1 may be a source node or a drain node, and the third node N3 may be a drain node or a source node. Hereinafter, for convenience of explanation, it will be described a case in which the second node N2 is a gate node, the first node N1 is a source node, and the third node N3 is a drain node in the driving transistor DT.

The scan transistor ST included in the subpixel circuit SPC illustrated in FIG. 2 may be a switching transistor for transmitting a data signal VDATA, which is an image signal, to the second node N2 which is the gate node of the driving transistor DT.

The scan transistor ST may be controlled on-off by the scan signal SC which is a gate signal applied through the scan line SCL as a type of gate line GL, and may control the electrical connection between the second node N2 of the driving transistor DT and the data line DL. The drain electrode or source electrode of the scan transistor ST may be electrically connected to the data line DL, and the source electrode or drain electrode of the scan transistor ST may be electrically connected to the second node N2 of the driving transistor DT. The gate electrode of the scan transistor ST may be electrically connected to the scan line SCL.

The storage capacitor Cst may be electrically connected between the first node N1 and the first node N2 of the driving transistor DT. The storage capacitor Cst may include a first capacitor electrode electrically connected to the first node N1 of the driving transistor DT or corresponding to the first node N1 of the driving transistor DT, and a second capacitor electrode electrically connected to the second node N2 of the driving transistor DT or corresponding to the second node N2 of the driving transistor DT.

The storage capacitor Cst may be an external capacitor intentionally designed outside the driving transistor DT rather than a parasitic capacitor (e.g., Cgs, Cgd) as an internal capacitor which may exist between the first node N1 and the second node N2 of the driving transistor DT.

Each of the driving transistor DT and the scan transistor ST may be an n-type transistor or a p-type transistor.

The display panel 110 may have a top emission structure or a bottom emission structure.

If the display panel 110 has a top emission structure, at least a portion of the subpixel circuit SPC may overlap with at least a portion of the light emitting device ED in the vertical direction. Accordingly, the area of the emission area may be increased and the aperture ratio may be increased.

If the display panel 110 has a bottom emission structure, the subpixel circuit SPC may not overlap with the light emitting device ED in the vertical direction.

As shown in FIG. 2, the subpixel circuit SPC may have a 2T-1C structure including two transistors T1 and T2 and one capacitor Cst. In some case, the subpixel circuit SPC may further include one or more transistors or one or more capacitors.

For example, the subpixel circuit SPC may have an 8T-1C structure including eight transistors and a single capacitor. For another example, the subpixel circuit SPC may have a 6T-2C structure including six transistors and two capacitors. For another example, the subpixel circuit SPC may have a 7T-1C structure including seven transistors and one capacitor.

Depending on the structure of the subpixel circuit SPC, there may vary the type and number of gate signal and/or gate lines supplied to the subpixel SP. In addition, depending on the structure of the subpixel circuit SPC, there may vary the type and number of common pixel driving voltages supplied to the subpixel SP.

Since circuit elements within each subpixel SP (in particular, light emitting devices EDs implemented with organic light emitting diodes (OLEDs) containing organic materials) are vulnerable to external moisture or oxygen, an encapsulation layer 200 may be disposed on the display panel 110 to prevent oxygen from penetrating into the circuit elements (particularly, the light emitting device ED). The encapsulation layer 200 may be configured in various shapes to prevent the light emitting device ED from coming into contact with moisture or oxygen.

Referring to FIG. 2, to sense a touch of a user, the display device 100 according to aspects of the present disclosure may include a touch sensor layer TSL including a plurality of sensor electrodes, a touch driving circuit 170 configured to sense a plurality of sensor electrodes, and a touch controller 180 configured to determine the presence or absence of a touch or touch coordinates using the sensing result (i.e., touch sensing data) of the touch driving circuit 170.

The touch sensor layer TSL may be built or embedded into the display panel 110. For example, the touch sensor layer TSL may be disposed on the encapsulation layer 200 within the display panel 110.

The display panel 110 may further include a plurality of touch pads to which the touch sensing circuit 170 is electrically connected, and a plurality of touch routing lines TL for electrically connecting a plurality of sensor electrodes included in the touch sensor layer TSL and a plurality of touch pads to which the touch sensing circuit 170 is connected.

Meanwhile, the display device 100 according to an aspect of the present disclosure may have an extremely narrow bezel structure in which the non-display area NDA of the display panel 110 is very small or almost absent.

Hereinafter, it will be described the extremely narrow bezel structure of the display panel 110 of the display device 100 according to an aspect of the present disclosure.

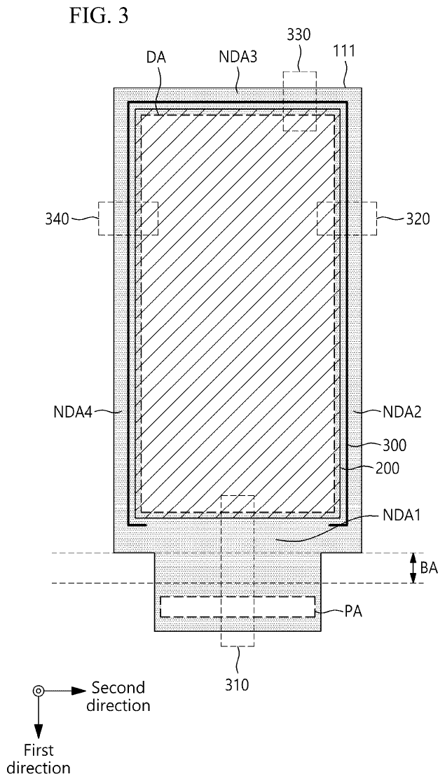

FIG. 3 illustrates a substrate 111 of a display panel 110 according to aspects of the present disclosure.

Referring to FIG. 3, the substrate 111 of the display panel 110 according to aspects of the present disclosure may include a display area DA in which an image is displayed and a non-display area NDA in which an image is not displayed.

Referring to FIG. 3, the non-display area NDA may include a first non-display area NDA1 located in a first direction from the display area DA, a second non-display area NDA2 located in a second direction from the display area DA, a third non-display area NDA3 located in a direction opposite to the first direction from the display area DA, and a fourth non-display area NDA4 located in a direction opposite to the second direction from the display area DA. For example, the first direction may be a column direction (e.g., Y-axis direction), and the second direction crossing the first direction may be a row direction (e.g., X-axis direction).

Referring to FIG. 3, the first non-display area NDA1 may include a pad area PA where a plurality of pads are disposed. Alternatively, the pad area PA may not be included in the first non-display area NDA1 and may extend from the first non-display area NDA1.

There may be disposed a plurality of pads to which the driving circuit is electrically connected in the pad area PA. A plurality of driving circuits or printed circuit boards may be electrically connected in the pad area. For example, the plurality of pads may include a plurality of display pads and a plurality of touch pads. A plurality of data lines, a first common driving voltage line VDDL, a second common driving voltage line VSSL may be electrically connected to the plurality of display pads. A plurality of touch routing lines TL may be electrically connected to the plurality of touch pads.

Referring to FIG. 3, the first non-display area NDA1 may further include a bending area BA. The bending area BA may be located between the first non-display area NDA1 and the pad area PA. In this case, the substrate 111 may be a flexible substrate. In some cases, the first non-display area NDA1 may not include the bending area BA.

Referring to FIG. 3, the display panel 110 may further include a ground line disposed in the non-display area NDA of the substrate 111. The ground line may be disposed from one point in the pad area PA to another point in the pad area PA via the second non-display area NDA2, the third non-display area NDA3, and the fourth non-display area NDA4.

Referring to FIG. 3, in the display panel 110 according to aspects of the present disclosure, the encapsulation layer 200 may have a structure in which an inorganic layer and an organic layer are stacked. In this case, an edge of the encapsulation layer 200 may be considered as an edge of the organic layer.

Referring to FIG. 3, the substrate 111 of the display panel 110 according to aspects of the present disclosure may include a groove 300 located outside the display area DA. That is, the groove 300 formed in the substrate 111 may be located along the non-display area NDA.

Referring to FIG. 3, the groove 300 may be formed on the furnace substrate 111 in a form of a trench along the second non-display area NDA2, the third non-display area NDA3 and the fourth non-display area NDA4.

Referring to FIG. 3, the groove 300 may not be formed in the substrate 111 in at least a portion of the first non-display area NDA1. At least a portion of the first non-display area NDA1 in which the groove 300 is not formed in the substrate 111 may be an area between the display area DA and the pad area PA.

Referring to FIG. 3, the groove 300 formed in the substrate 111 may have a U-shape.

Referring to FIG. 3, the display panel 110 may include a first area 310, a second area 320, a third area 330, and a fourth area 340. In the display panel 110, the first area 310 may include a display area DA and a first non-display area NDA1, and the second area 320 may include a display area DA and a second non-display area NDA2, the third area 330 may include a display area DA and a third non-display area NDA), and the fourth area 340 may include a display area DA and a fourth non-display area NDA4.

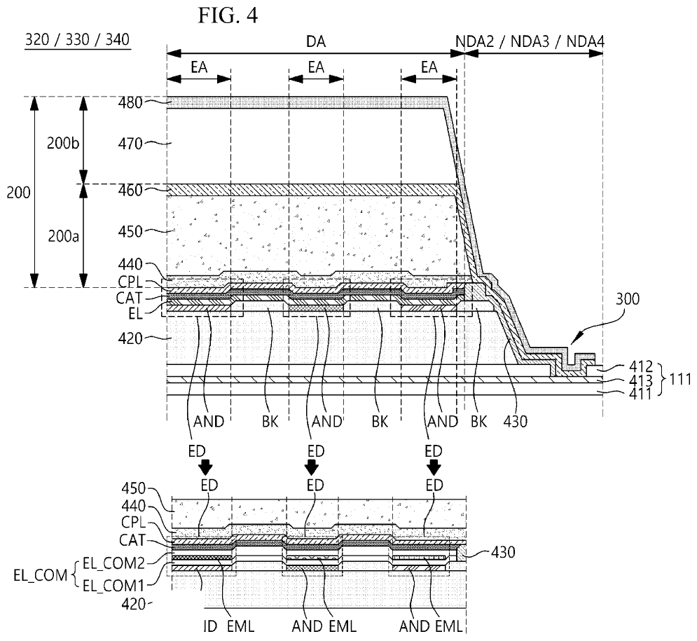

FIG. 4 is a cross-sectional view of the display panel 110 according to aspects of the present disclosure, and illustrates the second area 320, the third area 330, and the fourth area 340.

Referring to FIG. 4, the display panel 110 according to aspects of the present disclosure may include a substrate 111 including a display area DA on which a plurality of subpixels SP are dispose, a non-display area NDA located outside the display area DA, and a pad area PA, an insulating layer 420 disposed on the substrate 111, and a bank BK disposed on the insulating layer 420 and having a plurality of openings.

Referring to FIG. 4, in the display panel 110 according to aspects of the present disclosure, the second area 320 may include a display area DA and a second non-display area NDA2, the third area 330 may include a display area DA and a third non-display area NDA3, and the fourth area 340 may include a display area DA and a fourth non-display area NDA4.

Referring to FIG. 4, in the second area 320, third area 330, and fourth area 340, the substrate 111 may have the second non-display area NDA2, the third non-display area NDA3, and the fourth non-display area NDA4, respectively.

Referring to FIG. 4, the substrate 111 may include a groove 300 in the second area 320, third area 330 and fourth area 340. Accordingly, the groove 300 formed in the substrate 111 may be located in the second non-display area NDA2, the third non-display area NDA3, and the fourth non-display area NDA4.

Referring to FIG. 4, the insulating layer 420 may serve as a planarization layer. Although subpixel circuits SPC are omitted in FIG. 4, they may be disposed between the substrate 111 and the insulating layer 420.

Referring to FIG. 4, the bank BK may have a plurality of openings for defining the emission areas EA of the plurality of subpixels SP. A light emitting device ED may be formed in each of the plurality of openings of the bank BK. Accordingly, each of the plurality of openings of the bank BK may correspond to the emission area EA.

Referring to FIG. 4, each light emitting device ED may include an anode AND, an intermediate layer EL and a cathode CAT. The intermediate layer EL may include a common intermediate layer EL_COM and an emission layer EML.

Referring to FIG. 4, the common intermediate layer EL_COM may include a first common intermediate layer EL_COM1 and a second common intermediate layer EL_COM2. The first common intermediate layer EL_COM1 may be located between the anode AND and the emission layer EML, and the second common intermediate layer EL_COM2 may be located between the emission layer EML and the cathode CAT.

Referring to FIG. 4, the emission layer EML may be an individual layer disposed for each light emitting device ED. In comparison, the common intermediate layer EL_COM may be a common layer included in all of the plurality of light emitting devices ED. That is, the common intermediate layer EL_COM may be disposed throughout the display area DA.

Referring to FIG. 4, the display panel 110 according to aspects of the present disclosure may further include a barrier layer 430 extending from an upper portion or a top of the bank BK to the groove 300. For example, the barrier layer 430 may be an insulating film containing an insulating material.

Referring to FIG. 4, the substrate 111 may include a first substrate 411 and a second substrate 412 on the first substrate 411, and may further include a substrate intermediate layer 413 disposed between the first substrate 411 and the second substrate 412.

For example, each of the first substrate 411 and the second substrate 412 may be a polyimide (PI) layer. The substrate intermediate layer 413 may be an inorganic insulating layer. When a charge is charged to the first substrate 411 which is a polyimide layer, the substrate intermediate layer 413 may block charges from affecting the transistors disposed on the second substrate 412 through the second substrate 412 which is a polyimide layer. Additionally, the substrate intermediate layer 413 may block moisture components from penetrating upward through the first substrate 411 which is a polyimide layer. For example, the substrate intermediate layer 413 may be formed of a single layer of silicon nitride (SiNx) or silicon oxide (SiOx) or a multilayer thereof, or may be formed of a double layer of silicon dioxide (SiO2) and silicon nitride (SiNx), but is not limited thereto.

As described above, in the case that the substrate 111 includes the first substrate 411 and the second substrate 412, the groove 300 may be formed on the second substrate 412, which is an upper substrate, among the first substrate 411 and the second substrate 412.

Referring to FIG. 4, the barrier layer 430 may be disposed to extend from the outermost upper part of the bank BK to the inside of the groove 300 along the side of the insulating layer 420.

As described above, the display panel 110 may include a plurality of anodes AND located on the insulating layer 420 and each disposed in a plurality of emission areas EA, a first common intermediate layer EL_COM1 commonly located on the plurality of anodes AND, a plurality of emission layers EML located on the first common intermediate layer EL_COM1 and each disposed in a plurality of emission areas EA, a second common intermediate layer EL_COM2 commonly located on the plurality of emission layer EML, and a cathode CAT located on the second common intermediate layer EL_COM2.

The first common intermediate layer EL_COM1, the second common intermediate layer EL_COM2, and the cathode CAT may be disposed on the inner side of the barrier layer 430. However, the first common intermediate layer EL_COM1, the second common intermediate layer EL_COM2, and the cathode CAT may not be disposed on the barrier layer 430.

Referring to FIG. 4, the display panel 110 according to aspects of the present disclosure may further include a capping layer CPL disposed on the cathode CAT. The capping layer CPL may be disposed only on the inner side of the barrier layer 430, and may not be disposed on an upper portion or a top of the barrier layer 430. That is, the first common intermediate layer EL_COM1, the second common intermediate layer EL_COM2, the cathode CAT, and the capping layer CPL may be disposed only up to the outermost opening of the bank BK, and may not be disposed on an upper portion or a top of the barrier layer 430 located on the side of the outermost opening of the bank BK.

Referring to FIG. 4, the display panel 110 according to aspects of the present disclosure may include a first protective film 440 disposed on the cathode CAT, a first foreign matter protective layer 450 disposed on the first protective film 440, and a second protective film 460 disposed on the first foreign matter protective layer 450. For example, each of the first protective film 440 and the second protective film 460 may be an inorganic film, and the first foreign matter protective layer 450 may be an organic film.

The first protective film 440 may be composed of a single layer film or a multilayer film.

When the first protective film 440 is composed of a multilayer film, for example, the first protective film 440 may have a double membrane structure including a first material protective film with a first material and a second material protective film with a second material.

The first material protective film may be disposed on the capping layer, and the second material protective film may be disposed on the first material protective film.

The first material and the second material for forming the double layer structure of the first protective film 440 may be different materials. For example, the first material may include silicon oxide (SiOx), and the second material may include silicon nitride (SiNx). The first material protective film may have a thickness smaller than a thickness of the second material protective film.

The second protective film 460 may be composed of a single layer. For example, the second protective film 460 may include the same material as one of the first and second material protective film included in the first protective film 440. As an example, the second protective film 460 may include the same material (i.e., second material) as the second material protective film included in the first protective film 440.

Referring to FIG. 4, the outermost portion of the first protective film 440 may be located on an upper portion of the barrier layer 430 or on the inner side of the barrier layer 430.

In comparison, the second protective film 460 may be disposed to extend further outward than the first protective film 440. As an example, the second protective film 460 may extend along the sides of the first foreign matter protective layer 450 and the insulating layer 420. More specifically, the second protective film 460 may extend along the side of the first foreign matter protective layer 450, and may further extend to the groove 300 along an outer side of the barrier layer 430 located on the side of the insulating layer 420.

Referring to FIG. 4, the display panel 110 according to aspects of the present disclosure may further include a second foreign matter protective layer 470 disposed on the second protective film 460, and a buffer layer 480 disposed on the second foreign matter protective layer 470.

Referring to FIG. 4, the buffer layer 480 may extend along the sides of the second foreign matter protective layer 470, the first foreign matter protective layer 450, and the insulating layer 420. More specifically, the buffer layer 480 may extend along the side of the second foreign matter protective layer 470, may extend further along the side of the second protective film 460 located on the side of the first foreign matter protective layer 450, and may further extend to the groove 300 or an outer edge of the groove 300 along the side of the barrier layer 430 and the second protective film 460 located on the side of the insulating layer 420.

Referring to FIG. 4, the encapsulation layer 200 may include a first encapsulation layer 220a and a second encapsulation layer 220b. The first encapsulation layer 220a may include the first protective film 440, the first foreign matter protective layer 450, and the second protective film 460. The second encapsulation layer 220b may include the second foreign matter protective layer 470 and the buffer layer 480.

Referring to FIG. 4, in the display panel 110 according to aspects of the present disclosure, the barrier layer 430 may be a layer included in the encapsulation layer 200.

Referring to FIG. 4, at least one of the barrier layer 430, the second protective film 460, and the buffer layer 480 may be disposed to extend to the inside of the groove 300. That is, at least one of the barrier layer 430, the second protective film 460, and the buffer layer 480 may be located inside the groove 300.

Referring to FIG. 4, in the display panel 110 according to aspects of the present disclosure, the side of the insulating layer 420, the barrier layer 430, the second protective film 460, and the buffer layer 480 may overlap in a horizontal direction. This overlapping structure may be a “moisture penetration prevention structure” for preventing moisture from penetrating into the interior of the display panel 110.

As described above, by using the barrier layer 430 having a structure related to the groove 300 of the substrate 111, the display panel 110 according to aspects of the present disclosure may implement an extremely narrow bezel while preventing the overflow of an organic layer (e.g., the first foreign matter protective layer 450 and the second foreign matter protective layer 470) included in the encapsulation layer 200 to prevent moisture and oxygen from penetrating.

In addition, the display panel 110 according to aspects of the present disclosure may have a longer moisture permeability path, and may effectively prevent moisture penetration by using the barrier layer 430 having a structure linked to the groove 300 of the substrate 111

In addition, in the display panel 110 according to aspects of the present disclosure, the moisture permeability path expansion structure utilizing the groove 300 and the barrier layer 430 of the substrate 111 may be configured without increasing the bezel size. Therefore, it is possible to achieve an extremely narrow bezel while effectively preventing moisture penetration.

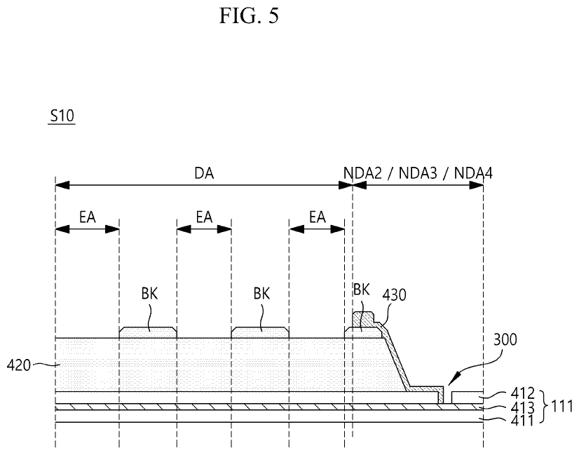

FIGS. 5 to 14 illustrate a manufacturing process (S10 to S100) of the display panel 110 according to aspects of the present disclosure.

Referring to FIG. 5, a substrate 111 including a first substrate 411, a substrate intermediate layer 413, and a second substrate 412 is formed in a first process step S10.

Each of the first substrate 411 and the second substrate 412 may be a polyimide (PI) layer. The substrate intermediate layer 413 may be an inorganic insulating layer.

A display area DA and a non-display area NDA may be defined on the substrate 111. A plurality of light emission areas EA may be defined in the display area DA. The non-display area NDA may include a first non-display area NDA1, a second non-display area NDA2, a third non-display area NDA3, and a fourth non-display area NDA4.

Referring to FIG. 5, in a first process step S10, a trench-shaped groove 300 may be disposed within in the second non-display area NDA2, the third non-display area NDA3, and the fourth non-display area NDA4 of the substrate 111. The groove 300 may have a U-shape.

The reason for forming the groove 300 in the second substrate 412 is to increase the length of the path through which moisture penetrates from the outside to the inside (i.e., the moisture permeability path length).

Referring to FIG. 5, in the first process step S10, an insulating layer 420 may be formed on the substrate 111. The insulating layer 420 may be a type of planarization layer. Before forming the insulating layer 420, there may be formed the transistors and capacitors to form subpixel circuits SPC, and various signal lines on the substrate 111.

Referring to FIG. 5, in the first process step S10, a bank BK having a plurality of openings may be formed on the insulating layer 420. The plurality of openings may correspond to the plurality of emission areas EA.

Referring to FIG. 5, in the first process step S10, the barrier layer 430 may extend from the outermost upper part of the bank BK along the outermost side of the bank BK and the side of the insulating layer 420, and may be disposed inside the groove 300 formed in the second substrate 412.

As the barrier layer 430 is disposed on the outer side of the insulating layer 420, the length of the path through which moisture may penetrate from the outside to the inside of the display panel 110 (i.e., the moisture permeability path length) may increase, thereby further preventing the moisture permeability.

The bank BK and the barrier layer 430 located thereon may serve to prevent overflow of the organic layer included in the encapsulation layer 200 disposed on the light emitting devices.

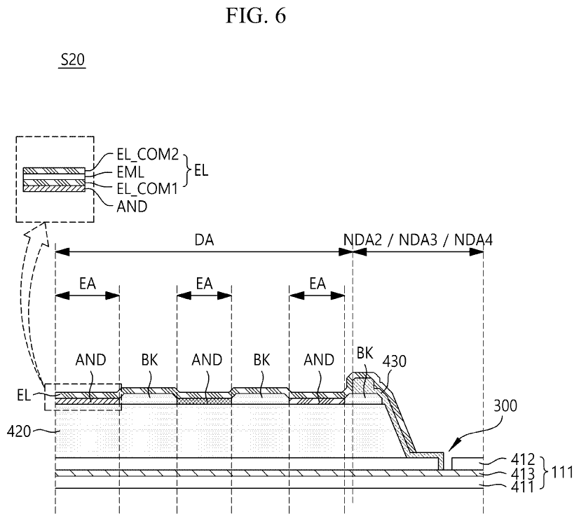

Referring to FIG. 6, in a second process step S20, there may be disposed an intermediate layer EL for forming light emitting device.

The intermediate layer EL may include a first common intermediate layer EL_COM1 on the anode AND, an emission layer EML on the first common intermediate layer EL_COM1, and a second common intermediate layer EL_COM2 on the emission layer EML. In this case, the intermediate layer EL may extend along an upper portion or a top of the barrier 430 to the lower portion of the outer surface of the insulating layer 420.

Before the bank BK is formed in the first process step S10, the anodes AND shown in FIG. 6 may be formed on the insulating layer 42.

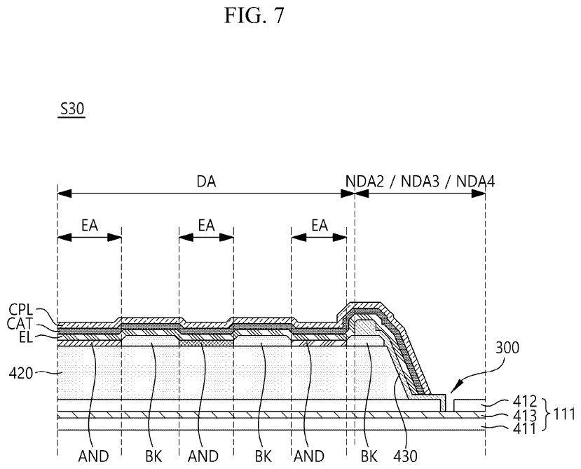

Referring to FIG. 7, in a third process step S30, a cathode CAT may be formed on the intermediate layer EL, and a capping layer CPL may be formed on the cathode CAT. In this case, the cathode CAT and capping layer CPL may extend along an upper portion or a top of the barrier 430 to the lower portion of the outer side of the insulating layer 420.

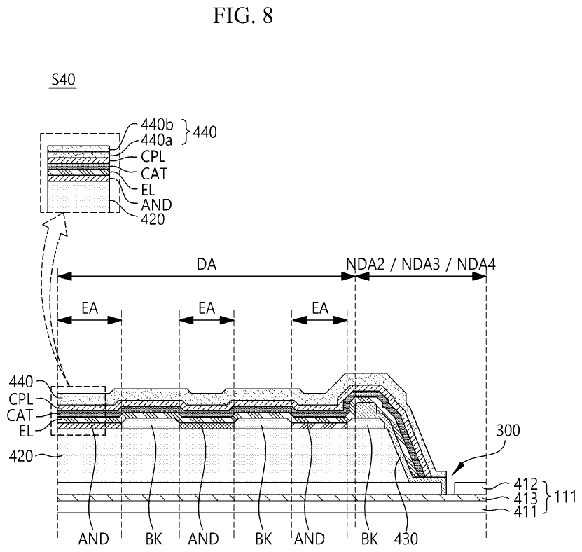

Referring to FIG. 8, in a fourth process step S40, a first protective film 440 may be formed on the capping layer CPL.

The first protective film 440 may have a double-layer structure formed using two process methods.

First, according to a first process method, a first material protective film 440a containing a first material may be formed on the capping layer CPL. Thereafter, a second material protective film 440b may be formed on the first material protective film 440a according to a second process method.

For example, the first process method may be an atomic layer deposition (ALD), and the second process method may be a chemical vapor deposition (CVD).

For example, the first material may include silicon oxide (SiOx), and the second material may include silicon nitride (SiNx). That is, the first material protective film 440a may be a silicon oxide film, and the second material protective film 440b may be a silicon nitride film.

For example, the first material protective film 440a may have a thickness smaller than a thickness of the second material protective film 440b.

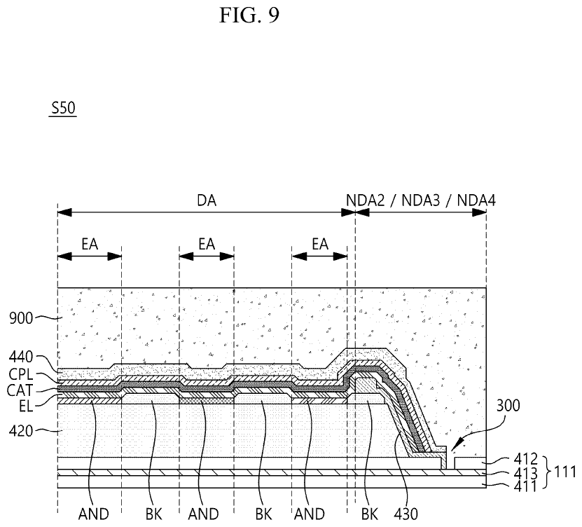

Referring to FIG. 9, in a fifth process step S50, a dry pattern forming film 900 capable of forming an ultraviolet pattern may be manufactured and laminated (or bonded) on the result of the fourth process step S40.

After adding 20 parts by weight of polyacrylate with an acid value of 100, 10 parts by weight of polyethylene glycol dimethacrylate, 10 parts by weight of trimethylpropane triacrylate, and 0.1 parts by weight of 4, 4-bis(diethylamino) benzophenone as an initiator to 60 parts by weight of ethyl ketone and stirring, a photosensitive composition may be coated on an oxygen blocking film and then dried to form a film having a predetermined film thickness.

An upper surface of the film formed in this way is protected with a release film, and the photosensitive composition between the upper and lower films (e.g., coral blocking film, release film) may be patterned to form a dry pattern forming film 900 to form the first foreign matter protective layer 450.

When laminating the dry pattern forming film 900 to form the first foreign matter protective layer 450, there may be laminated using a laminator of a predetermined temperature under the conditions of a predetermined pressure and a predetermined roll speed.

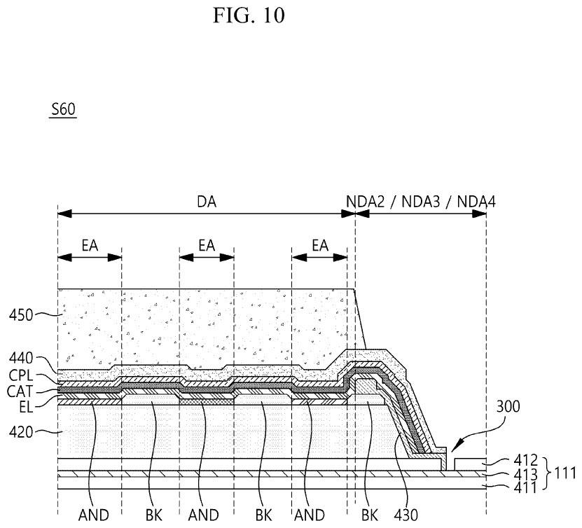

Referring to FIG. 10, in a sixth process step S60, there may be performed an exposure treatment using a mask capable of forming a desired pattern. After exposure treatment, the first foreign matter protective layer 450 may be formed from the dry pattern forming film 900 manufactured in the fifth process step S50 using an alkaline developer.

Referring to FIG. 10, in the sixth process step S60, an exposure process may be performed using a mask capable of forming a desired pattern. After exposure process, the first foreign matter protective layer 450 may be formed from the dry pattern forming film 900 manufactured in the fifth process step S50 using an alkaline developer.

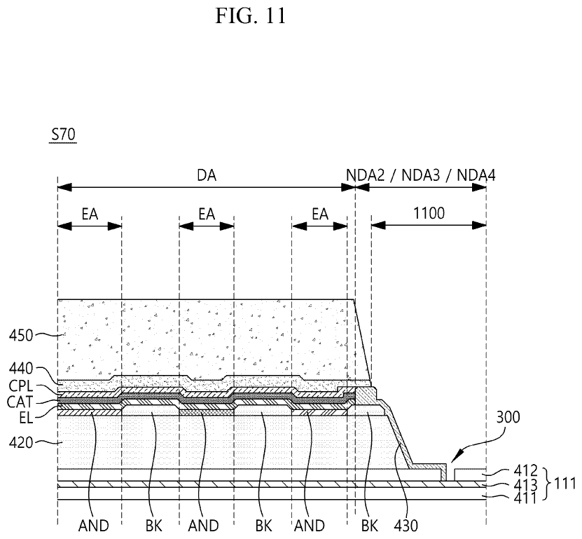

Referring to FIG. 11, in a seventh process step S70, a dry etching process may be performed on the product manufactured in the sixth process step S60 using a hard mask. Accordingly, the first protective film 440, the capping layer CPL, the cathode CAT, and the intermediate layer EL may be removed from the undesired area 1100.

Referring to FIG. 11, the area 1100 from which the first protective film 440, the cathode CAT, and the intermediate layer EL are to be removed may be from the outermost upper point of the bank BK to the outer end of the substrate 111.

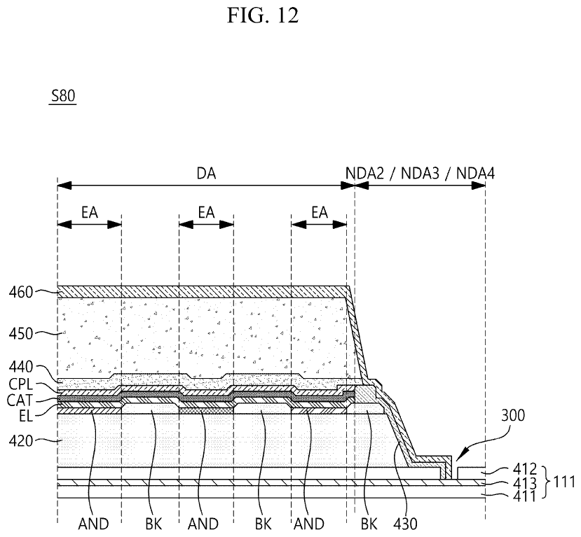

Referring to FIG. 12, in an eighth process step S80, the second protective film 460 may be disposed on the first foreign matter protective layer 450. The second protective film 460 may be disposed along the side as well as the top of the first foreign matter protective layer 450, and may extend to the lower side of the insulating layer 420. The second protective film 460 may be disposed while covering the barrier 430 located on the side of the insulating layer 420.

The second protective film 460 may be formed according to a second process method. For example, the second process method may be the chemical vapor deposition (CVD). The second protective film 460 may include silicon oxide (SiOx) or silicon nitride (SiNx).

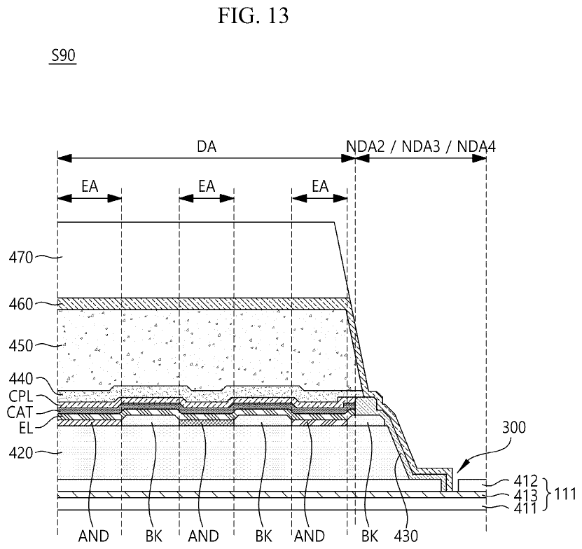

Referring to FIG. 13, in a ninth process step S90, a second foreign matter protective layer 470 may be formed on the second protective film 460. The second foreign matter protective layer 470 may extend along the second protective film 460 to the lower portion of the outer surface of the insulating layer 420. The second foreign matter protective layer 470 may be disposed to cover the second protective film 460.

Referring to FIG. 13, in the ninth process step S90, the second foreign matter protective layer 470 may be formed in the same manner as the first foreign matter protective layer 450, or, alternatively, may be formed of an organic insulating film through a low-temperature process.

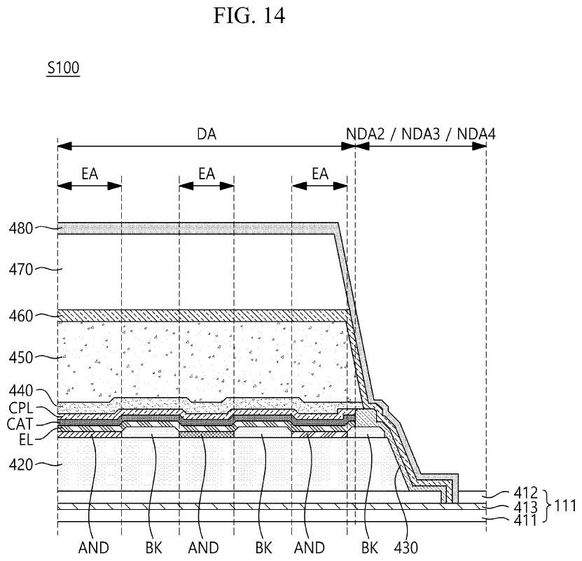

Referring to FIG. 14, in a tenth process step S100, the buffer layer 480 may be disposed on the second foreign matter protective layer 470. The buffer layer 480 may be disposed to extend along the side of the second foreign matter protective layer 470, the side of the first foreign matter protective layer 450, and the side of the insulating layer 420.

Referring to FIG. 14, in the tenth process step S100, the buffer layer 480 may be disposed to cover the second foreign matter protective layer 470.

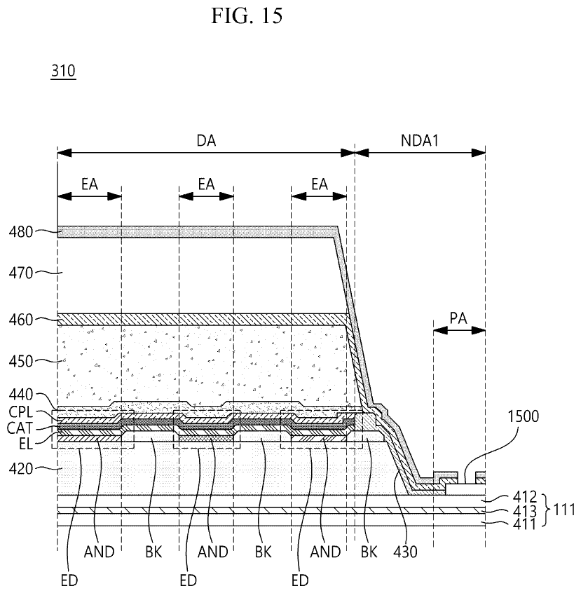

FIG. 15 is another cross-sectional view of the display panel 110 according to aspects of the present disclosure, and is a cross-sectional view of the first area 310.

Referring to FIG. 15, the display panel 110 according to aspects of the present disclosure may include a substrate 111 including a display area DA on which a plurality of subpixels SP are disposed and a non-display area NDA located outside the display area DA and including a pad area PA, an insulating layer 420 disposed on the substrate 111, and a bank BK disposed on the insulating layer 420 and having a plurality of openings.

Referring to FIG. 15, in the display panel 110 according to aspects of the present disclosure, a first area 340 may include a display area DA and a first non-display area NDA1. The first non-display area NDA1 may include a pad area PA.

Referring to FIG. 15, a groove 300 may not be formed in the substrate 111 in the first non-display area NDA1. Accordingly, the barrier layer 430 may be disposed to extend to the side of a pad 1500 disposed in the pad area PA.

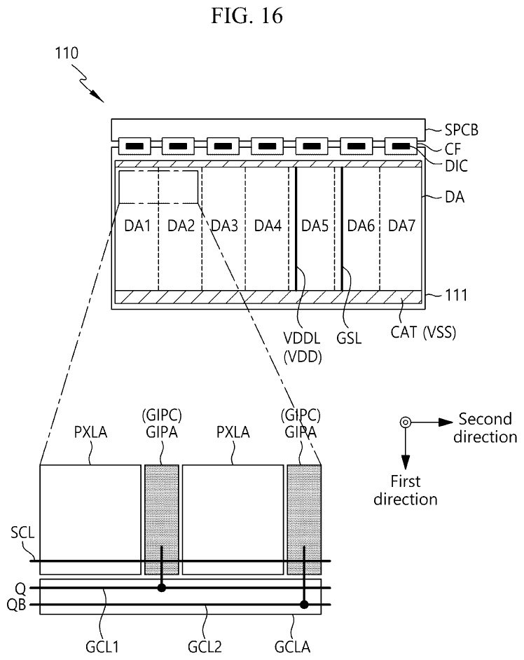

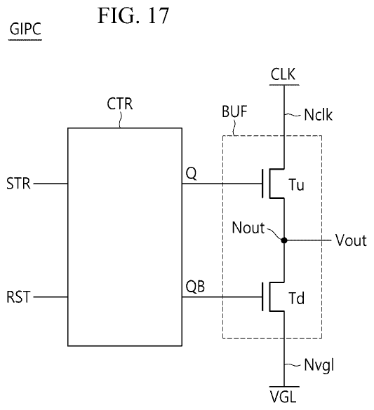

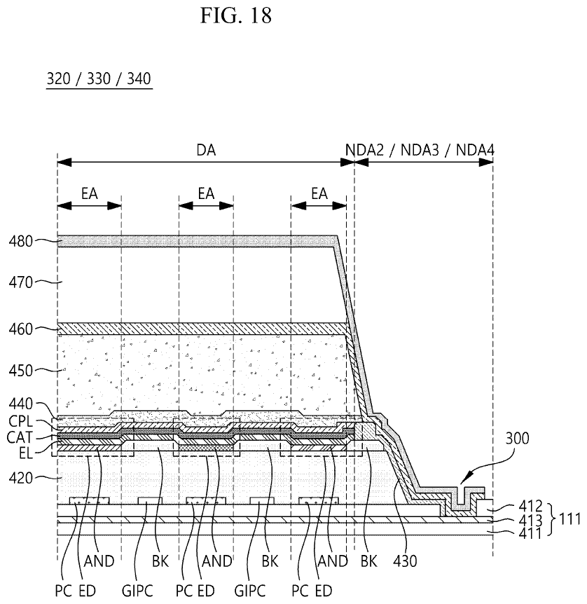

FIG. 16 is a plan view of the display panel 110 according to aspects of the present disclosure, FIG. 17 briefly illustrates a gate-in-panel circuit GIPC according to aspects of the present disclosure, and FIG. 18 is another cross-sectional view of the display panel 110 according to aspects of the present disclosure. The cross-sectional view of FIG. 18 is different from the cross-sectional view of FIG. 4 in that a plurality of gate-in-panel circuits GIPC and a plurality of pixel circuits PC are further illustrated, but the rest is the same as the cross-sectional view of FIG. 4. In the description referring to FIG. 18, it will be mainly explained the differences from FIG. 4.

Referring to FIG. 16, a circuit film CF on which a driving integrated circuit DIC is mounted may be connected between one side of the substrate 111 of the display panel 110 and a source printed circuit board SPCB. For example, the driving integrated circuit DIC may be implemented as a chip-on-film type mounted on the circuit film CF. The driving integrated circuit DIC may be an integrated circuit which implements the data driving circuit 120, or may be an integrated circuit including the data driving circuit 120 and the touch driving circuit 170.

Referring to FIG. 16, the gate driving circuit 130 according to aspects of the present disclosure may include a plurality of gate-in-panel circuits GIPC for supplying gate signals to a plurality of subpixels SP.

Referring to FIG. 16, the gate driving circuit 130 according to aspects of the present disclosure may be not disposed in or connected to the non-display area NDA. Instead, the gate driving circuit 130 according to aspects of the present disclosure may be disposed in the display area DA.

Referring to FIG. 16, the display panel 110 according to aspects of the present disclosure may include a plurality of pixel areas PXLA and a plurality of gate driving circuit areas GIPA.

At least one subpixel SP among the plurality of subpixels SP may be disposed in each of the plurality of pixel areas PXLA.

At least one of a plurality of gate-in-panel circuits GIPC may be disposed in each of the plurality of gate driving circuit areas GIPA.

At least one gate-in-panel circuit GIPC disposed in each of the plurality of gate driving circuit areas GIPA may supply a gate signal to at least one subpixel SP disposed in each of the plurality of pixel areas PXLA.

Referring to FIG. 16, the display area DA may include a plurality of sub-display areas (e.g., DA1 to DA7). Each of the plurality of sub-display areas DA1 to DA7 may include at least one of the plurality of pixel areas PXLA and at least one of the plurality of gate driving circuit areas GIPA.

Referring to FIG. 16, each of the plurality of gate driving circuit areas GIPA may be disposed between two adjacent pixel areas PXLA among the plurality of pixel areas PXLA. Accordingly, as shown in FIG. 8, the gate-in-panel circuit GIPC included in each of the plurality of gate driving circuit areas GIPA may be disposed between the pixel circuits PC included in two adjacent pixel areas PXLA. Here, the pixel circuit PC may include two or more subpixel circuits SPC.

Referring to FIG. 16, each of the plurality of sub-display areas DA1 to DA7 may include at least one gate connection line area GCLA. In at least one gate connection line area GCLA, there may be disposed the connection lines GCL1 and GCL2 which electrically connect the gate-in-panel circuits GIPC arranged in the gate driving circuit areas GIPA separated by the pixel area PXLA.

The fact that the gate-in-panel circuits GIPC are electrically connected by the connection lines GCL1 and GCL2 may mean that the nodes required to have the same electrical state in the gate-in-panel circuits GIPC are connected by the connection lines GCL1 and GCL2.

For example, the display panel 110 according to aspects of the present disclosure may further include a first connection line GCL1 and a second connection line GCL2 which electrically connect two or more gate-in-panel circuits GIPC among a plurality of gate-in-panel circuits GIPC.

Each of the first connection line GCL1 and the second connection line GCL2 may be disposed to extend in a second direction. The scan line SCL may also be arranged to extend in the second direction. Accordingly, each of the first and second connection lines GCL1 and GCL2 may be disposed in parallel with the scan line SCL.

Referring to FIG. 18, the gate-in-panel circuit GIPC included in each of the plurality of gate driving circuit areas GIPA may overlap the bank BK, and the pixel circuit PC included in each of the plurality of pixel areas PXLA may overlap the emission area EA.

Referring to FIG. 16, the display panel 110 according to aspects of the present disclosure may further include a first connection line GCL1 and a second connection line GCL2 which electrically connect two or more gate-in-panel circuits GIPC among a plurality of gate-in-panel circuits GIPC.

Referring to FIG. 17, the display panel 110 according to aspects of the present disclosure may include a gate-in-panel circuit GIPC for supplying a gate signal to a plurality of subpixels SP.

The gate-in-panel circuit GIPC may be of the gate-in-panel type, and may be disposed in the display area DA.

The gate-in-panel circuit GIPC may include an output buffer BUF configured to output the gate signal Vout and a control circuit CTR configured to control the output buffer BUF.

The output buffer BUF may include a pull-up transistor Tu connected between a clock node Nclk receiving a clock signal CLK and an output node Nout outputting a gate signal Vout, and a pull-down transistor Td connected between the output node Nout outputting the gate signal Vout and a low voltage node Nvgl where a second gate voltage VGL is input.

The gate signal Vout may be the scan signal SC of FIG. 2.

The output node Nout may be electrically connected to a gate line GL such as a scan line SCL.

A gate node of the pull-up transistor Tu may correspond to a Q node. Depending on the voltage level of the Q node, the pull-up transistor Tu may be turned on or turned off.

A gate node of the pull-down transistor Td may correspond to a QB node. Depending on the voltage level of the QB node, the pull-down transistor Td may be turned on or turned off.

The voltage level of the Q node and the voltage level of the QB node may be opposite to each other. That is, when the voltage level of the Q node is a high level, the voltage level of the QB node may be a low level. When the voltage level of the Q node is a low level, the voltage level of the QB node may be a high level.

Since the voltage level of the Q node and the voltage level of the QB node are opposite to each other, the on-off state of the pull-up transistor Tu and the on-off state of the pull-down transistor Td may be different. That is, when the pull-up transistor Tu is turned on, the pull-down transistor Td may be turned off. When the pull-up transistor Tu is turned off, the pull-down transistor Td may be turned on.

The control circuit CTR may receive control signals such as a start signal STR and a reset signal RST, and may control the voltage level of the Q node and the voltage level of the QB node.

The control circuit CTR may include a plurality of transistors.

When the voltage level of the Q node becomes a high level and the voltage level of the QB node becomes a low level by the control circuit CTR, the pull-up transistor Tu may be turned on, and a gate signal Vout having a high level voltage of the clock signal CLK may be output from the output node Nout.

When the voltage level of the Q node becomes a low level and the voltage level of the QB node becomes a high level by the control circuit CTR, the pull-down transistor Td may be turned on, and a gate signal Vout having a second gate voltage VGL corresponding to a low level voltage may be output from the output node Nout.

Referring to FIG. 16, the display panel 110 according to aspects of the present disclosure may further include a first connection line GCL1 and a second connection line GCL2 which electrically connect two or more gate-in-panel circuits GIPC among a plurality of gate-in-panel circuits GIPC.

Referring to FIGS. 16 and 17, the first connection line GCL1 may be a line or a wire for electrically connecting the Q node, which is the gate node of the pull-up transistor Tu, in each of two or more gate-in-panel circuits GIPC separated by a pixel area PXLA.

Referring to FIGS. 16 and 17, the second connection line GCL2 may be a line or a wire for electrically connecting the QB node, which is the gate node of the pull-down transistor Td, in each of two or more gate-in-panel circuits GIPC separated by a pixel area PXLA.

Referring to FIG. 16, there may be disposed a cathode CAT to which a base voltage VSS is applied on the substrate 111 of the display panel 110.

In addition, in the substrate 111 of the display panel 110, at least one first common driving voltage line VDDL for transmitting the first common driving voltage VDD to at least one sub-display area (e.g., DA5) among the plurality of sub-display areas DA1 to DA7 may be disposed to extend in the first direction.

In addition, in the substrate 111 of the display panel 110, a plurality of gate driving-related signal lines GSL for transmitting the gate driving-related signals to at least one sub-display area (e.g., DA5) among the plurality of sub-display areas DA1 to DA7 may be disposed to extend in the first direction.

The plurality of gate driving-related signal lines GSL may include clock lines for transmitting clock signals to at least one gate-in-panel circuit GIPC.

The plurality of gate driving-related signal lines GSL may further include a high-level gate voltage line and a low-level gate voltage line for transferring a high-level gate voltage and low-level gate voltage to at least one gate-in-panel circuit GIPC.

The plurality of gate driving-related signal lines GSL may further include the control signal lines for transferring various control signals (e.g. start signal, reset signal, etc.) for gate driving to at least one gate-in-panel circuit GIPC.

The plurality of gate driving-related signal lines GSL may further include a high-potential voltage line for transmitting a high-potential voltage to at least one gate-in-panel circuit GIPC and a low-potential voltage line for transmitting a low-potential voltage to at least one gate-in-panel circuit GIPC.

As described above, the gate-in-panel circuit GIPC included in the gate driving circuit 130 is disposed in the display area DA, thereby implementing an extremely narrow bezel.

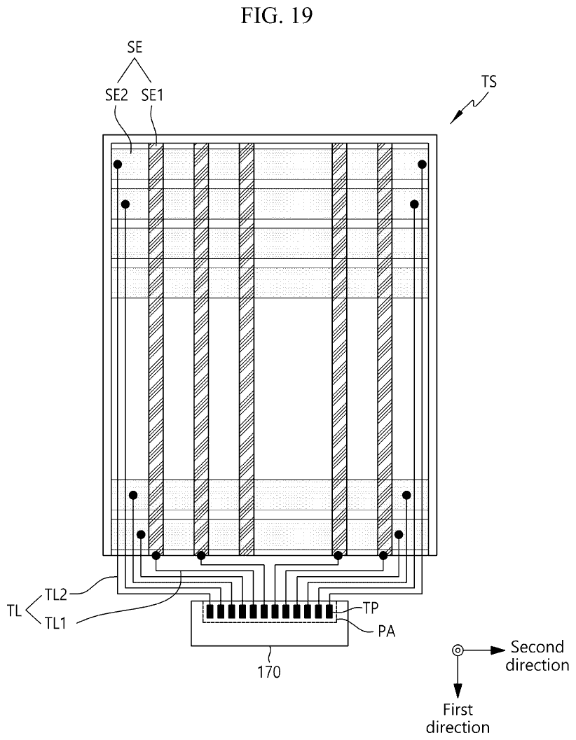

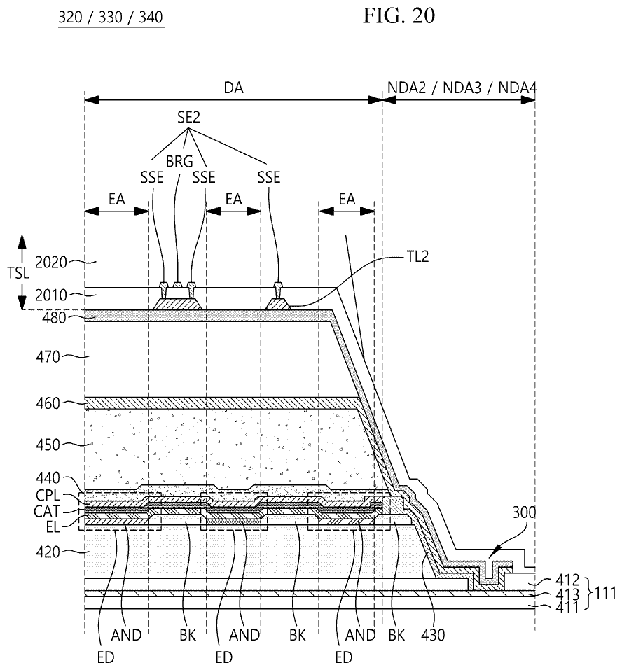

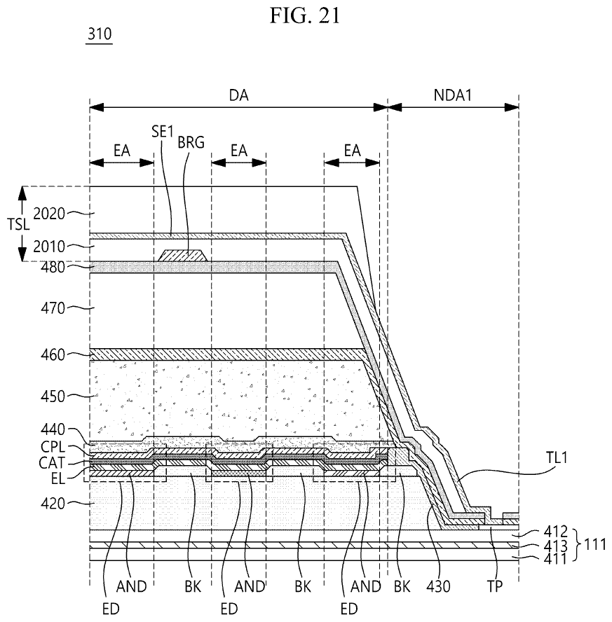

FIG. 19 illustrates a touch sensor TS included in the display panel 110 according to aspects of the present disclosure. FIG. 20 is a cross-sectional view of the second to fourth areas 320, 330 and 340 of the display panel 110 according to aspects of the present disclosure, and FIG. 21 is a cross-sectional view of the first area 310 of the display panel 110 according to aspects of the present disclosure.

Referring to FIG. 19, the display panel 110 according to aspects of the present disclosure may include a touch sensor TS for touch sensing.

Referring to FIGS. 19, 20 and 21, the display panel 110 according to aspects of the present disclosure may further include a plurality of sensor electrodes SE as a touch sensor TS disposed on the buffer layer 480. In addition, the display panel 110 may further include a plurality of touch routing lines TL corresponding to a plurality of sensor electrodes SE.

Referring to FIGS. 19 and 20, the plurality of touch routing lines TL may not be disposed in the second non-display area NDA2, the third non-display area NDA3, and the fourth non-display area NDA4.

Referring to FIGS. 19 and 21, at least a portion of the plurality of touch routing lines TL may extend across the display area DA to the pad area PA in the first non-display area NDA1.

Referring to FIG. 19, in the display panel 110 according to aspects of the present disclosure, the touch sensor TS may include a plurality of sensor electrodes SE. The plurality of sensor electrodes SE may include a plurality of first sensor electrodes SE1 and a plurality of second sensor electrodes SE2.

Each of the plurality of first sensor electrodes SE1 may be disposed to extend in a first direction, and each of the plurality of second sensor electrodes SE2 may be disposed to extend in a second direction intersecting the first direction. Here, the first direction may be the same as the direction in which the data line DL extends. The second direction intersecting the first direction may be the same as the direction in which the scan line SCL, which is the gate line GL, extends.

Referring to FIG. 19, the display panel 110 according to aspects of the present disclosure may include a plurality of touch pads TP to which the touch driving circuit 170 is electrically connected and disposed in the pad area PA.

In addition, the display panel 110 according to aspects of the present disclosure may further include a plurality of touch routing lines TL for electrically connecting the plurality of sensor electrodes SE to the plurality of touch pads TP.

The plurality of touch routing lines TL may include a plurality of first touch routing lines TL1 connected to a plurality of first sensor electrodes SE1, and a plurality of second touch routing lines TL2 connected to a plurality of second sensor electrodes SE2.

Referring to FIGS. 19 and 20, each of the plurality of first sensor electrodes SE1 may be composed of a plurality of sub-sensor electrodes SSE and bridge electrodes BRG connecting the sub-sensor electrodes SSE. Each of the plurality of second sensor electrodes SE2 may be formed as one body. In this case, the plurality of sub-sensor electrodes SSE included in each of the plurality of first sensor electrodes SE1 may include a touch sensor metal, and the plurality of second sensor electrodes SE2 may also include a touch sensor metal, and the bridge electrodes BRG included in each of the plurality of first sensor electrodes SE1 may include a bridge metal.

Alternatively, each of the plurality of second sensor electrodes SE2 may be composed of a plurality of sub-sensor electrodes and bridge electrodes connecting the sub-sensor electrodes. Each of the plurality of first sensor electrodes SE1 may be formed as one body. In this case, the plurality of sub-sensor electrodes included in each of the plurality of second sensor electrodes SE2 may include a touch sensor metal, and the plurality of first sensor electrodes SE1 may also include a touch sensor metal. The plurality of sub-sensor electrodes included in each of the plurality of second sensor electrodes SE2 may include a bridge metal.

The touch sensor metal for forming the touch sensor may be metal disposed within a touch sensor metal layer, and the bridge metal for electrically connecting the touch sensor metals may be metal disposed within a bridge metal layer. The touch sensor metal layer and the bridge metal layer may be separated with a sensor interlayer insulating layer therebetween.

Referring to FIGS. 19 and 21, each of a plurality of first touch routing lines TL1 may be connected to one end of the corresponding first sensor electrode SE1, or may be an extension line of the corresponding first sensor electrode SE1.

Referring to FIGS. 19 and 21, the plurality of first touch routing lines TL1 may be disposed within the first non-display area NDA1, and may be electrically connected to a plurality of touch pads TP in the pad area PA in the first non-display area NDA1.

Referring to FIGS. 19 and 20, each of a plurality of second touch routing lines TL2 may be connected to a portion of each of the plurality of second sensor electrodes SE2.

Referring to FIGS. 19 and 20, each of the plurality of second touch routing lines TL2 may be electrically connected to the corresponding second sensor electrode SE2 within the display area DA. Here, the second sensor electrode SE2 may include a plurality of sub-sensor electrodes SSE and a bridge BRG connecting the sub-sensor electrodes.

Referring to FIGS. 19 and 20, the plurality of second touch routing lines TL2 may not pass through the second to fourth non-display areas NDA2, NDA3 and NDA4, but may extend across the display area DA in the first direction to the first non-display area NDA1. In addition, the plurality of second touch routing lines TL2 may extend to the first non-display area NDA1, and may be electrically connected to the plurality of touch pads TP in the pad area PA within the first non-display area NDA1.

Referring to FIG. 19, each of the plurality of first touch routing lines TL1 may include a touch sensor metal or a bridge metal. Alternatively, each of the plurality of first touch routing lines TL1 may include a first line part including a touch sensor metal and a second line part including a bridge metal or another metal.

Referring to FIG. 19, each of the plurality of second touch routing lines TL2 may be disposed to extend across the display area DA to the pad area PA within the first non-display area NDA1. Accordingly, within the display area DA, each of the plurality of second touch routing lines TL2 may overlap with at least one second sensor electrode SE2.

Referring to FIG. 19, each of the plurality of second touch routing lines TL2 may include a bridge metal. Alternatively, each of the plurality of second touch routing lines TL2 may include a third line part including a bridge metal and a fourth line part including a touch sensor metal or another metal.

Referring to FIG. 21, each of the plurality of touch routing lines TL including the first touch routing line TL1 may extend along the outer sides of the second foreign matter protective layer 470, the first foreign matter protective layer 450, and the insulating layer 420, and may be electrically connected to a touch pad TP disposed in the pad area PA.

With reference to FIGS. 20 and 21, it will be described a vertical structure of the display panel 110 on which the touch sensor is additionally disposed.

Referring to FIGS. 20 and 21, a touch sensor layer TSL may be disposed on a buffer layer 480. The touch sensor layer TSL may include a bridge metal layer on the buffer layer 480, an interlayer insulating film 2010 on bridge metal layer, a touch sensor metal layer on the interlayer insulating film 2010, and a touch sensor protection layer 2020 on touch sensor metal layer.

Referring to FIGS. 20 and 21, the interlayer insulating film 2010 may be an inorganic insulating film or an organic insulating film. The touch sensor protection layer 2020 may be an organic insulating film.

Referring to FIGS. 20 and 21, the bridge metal layer may be a layer where a bridge BRG is disposed.

Referring to FIGS. 20 and 21, the touch sensor metal layer may be a layer where a plurality of sub-sensor electrodes SSE included in the plurality of first sensor electrodes SE1 are disposed, and may be a layer where a plurality of second sensor electrodes SE2 are disposed.

Referring to FIGS. 20 and 21, a plurality of touch routing lines TL may be disposed in at least one of the touch sensor metal layer and the bridge metal layer.

For example, as shown in FIG. 20, a plurality of second touch routing lines TL2 may be disposed in the bridge metal layer. The plurality of second touch routing lines TL2 may not pass through the second to fourth non-display areas NDA2 to NDA4, but may extend directly across the display area DA in the first direction to the first non-display area NDA1 to be disposed up to the pad area PA within the first non-display area NDA1.

For example, as shown in FIG. 21, a plurality of first touch routing lines TL1 may be disposed in the touch sensor metal layer. The plurality of first touch routing lines TL1 may be disposed within the first non-display area NDA1, and may be electrically connected to the touch pads TP included in the pad area PA within the first non-display area NDA1.

In more detail, referring to FIG. 21, the plurality of touch routing lines TL including the first touch routing lines TL1 may extend along the buffer layer 480 located on the side of the second foreign matter protective layer 470. In addition, the plurality of touch routing lines TL may further extend along the sides of the second protective film 460 and the buffer layer 480 located on the side of the first foreign matter protective layer 450. In addition, the plurality of touch routing lines TL may further extend along the sides of the barrier layer 430, the second protective film 460, and the buffer layer 480 located on the side of the insulating layer 420 to be electrically connected to a plurality of touch pads TP disposed in the pad area PA.

As described above, the touch routing lines TL and the second touch routing lines TL2 may be disposed extending across the display area DA to the pad area PA without bypassing a bezel (e.g., second non-display area NDA2, fourth non-display area NDA4, etc.), thereby implementing more effectively an extremely narrow bezel.

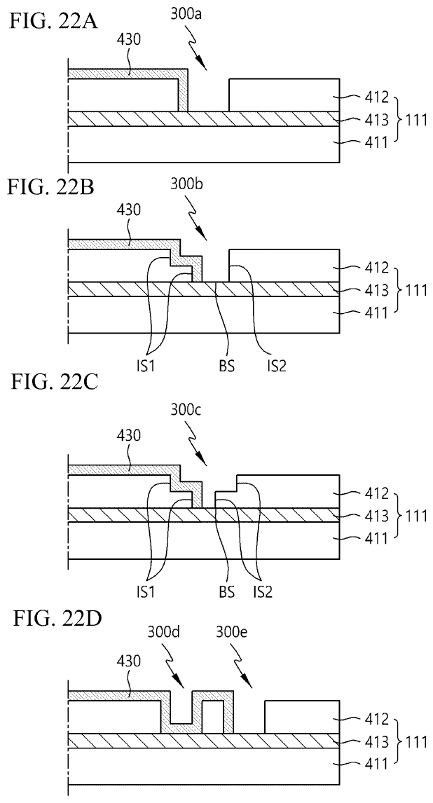

FIGS. 22A to 22D are examples of grooves 300a, 300b, 300c, 300d, and 300e formed in the substrate 111 of the display panel 110 according to aspects of the present disclosure.

Referring to FIGS. 22A to 22D, the substrate 111 of the display panel 110 according to aspects of the present disclosure may include a first substrate 411, a substrate intermediate layer 413, and a second substrate 412. This is only an example, and the substrate 111 of the display panel 110 according to aspects of the present disclosure may include one layer.

Referring to FIG. 22A, only one groove 300a may be formed in the second substrate 412. In this case, a barrier layer 430 may extend along an upper surface of the second substrate 412 to the inside of one groove 300a.

Referring to FIG. 22B, one groove 300b may be formed in the second substrate 412, and the groove 300b may include a first inner side IS1, a second inner side IS2, and a bottom surface BS connecting the first inner side IS1 and the second inner side IS2. The first inner side IS1 may be located closer to the display area DA than the second inner side IS2. At least one of the first inner side IS1 and the second inner side IS2 may include a plurality of steps.

For example, as shown in FIGS. 22A and 22B, among the first and second inner sides IS1 and IS2 of the groove 300b, the first inner side IS1 closer to the display area DA may have a plurality of steps. In this case, a barrier layer 430 may extend along the upper surface of the second substrate 412, and may be disposed on the first inner side surface IS1 of one groove 300b.

Referring to FIG. 22C, one groove 300c may be formed in the second substrate 412, and each of the first and second inner sides IS1 and IS2 of the groove 300c may include a plurality of steps. In this case, the barrier layer 430 may extend along the upper surface of the second substrate 412, and may be disposed on the first inner side IS1 of one groove 300c. The barrier layer 430 may be further disposed on the second inner side IS2.

Referring to FIG. 22D, two grooves 300d and 300e may be formed in the second substrate 412. In this case, the barrier layer 430 may extend along the upper surface of the second substrate 412 to the inside of the first groove 300d, which is closer to the display area DA among the two grooves 300d and 300e. The barrier layer 430 may further extend beyond the inside of the first groove 300d to at least a portion of the inside of the second groove 300e.

The shape and structure of the groove in the substrate 110 illustrated in FIG. 22 are only examples for convenience of explanation, and may be modified in various ways if the length of the moisture permeability path may be extended to prevent moisture permeation.

Aspects of the present disclosure described above are briefly described as follows.

A display device according to aspects of the present disclosure may include a substrate including a display area on which a plurality of subpixels are arranged, a non-display area located outside the display area and including a pad area, and a groove, an insulating layer disposed on the substrate, a bank disposed on the insulating layer and having a plurality of openings, and a barrier layer extending from an upper portion of the bank to the groove.

In the display device according to aspects of the present disclosure, the substrate may include a first substrate, a second substrate on the first substrate, and a substrate intermediate layer on the first substrate and the second substrate, and the groove may be formed in the second substrate.

The non-display area may include a first non-display area located outside the display area in a first direction and including the pad area, a second display area located outside the display area in a second direction different from the first direction, a third non-display area located outside the display area in a direction opposite to the first direction, and a fourth non-display area located outside the display area in a direction opposite to the second direction.

The groove may not be formed in at least a portion of the first non-display area, and may be formed in the form of a trench along the second non-display area, the third non-display area, and the fourth non-display area on the substrate.

The barrier layer may be disposed to extend from the outermost upper portion of the bank to an inside of the groove along a side of the insulating layer.

The display device according to aspects of the present disclosure may further include a plurality of anodes located on the insulating layer and each disposed in a plurality of emission areas, a first common intermediate layer commonly located on the plurality of anodes, a plurality of emission layers located on the first common intermediate layer and each disposed in the plurality of emission areas, a second common intermediate layer commonly located on the plurality of emission layers, and a cathode located on the second common intermediate layer.

The first common intermediate layer, the second common intermediate layer, and the cathode may be disposed on an inner side of the barrier layer, and may not be disposed on an upper portion of the barrier layer.

The display device according to aspects of the present disclosure may further include a capping layer disposed on the cathode. The capping layer may be disposed on an inner side of the barrier layer, and may be not disposed on an upper portion of the barrier layer.

The display device according to aspects of the present disclosure may further include a first protective film disposed on the cathode, a first foreign matter protective layer disposed on the first protective film, and a second protective film disposed on the first foreign matter protective layer. The first protective film may include a first material protective film including a first material, and a second material protective film including a second material different from the first material.

One of the first material protective film and the second material protective film may have a thinner thickness than the other due to differences in processing methods.

The outermost portion of the first protective film may be located on the upper portion or the inner side of the barrier layer.

The first protective film may include a first material protective film including a first material, and a second material protective film including a second material different from the first material.

The second protective film may be formed as a single layer.

The second protective film may extend along sides of the first foreign matter protective layer and the insulating layer.

The second protective film may be disposed to cover the first foreign matter protective layer and the insulating layer.

The display device according to aspects of the present disclosure may further include a second foreign matter protective layer disposed on the second protective film, and a buffer layer disposed on the second foreign matter protective layer.

The buffer layer may extend along sides of the second foreign matter protective layer, the first foreign matter protective layer, and the insulating layer. The buffer layer may be disposed to cover the second foreign matter protective layer, the first foreign matter protective layer, and the insulating layer.

At least one of the second protective film and the buffer layer may be located inside the groove.

A side of the insulating layer, the barrier layer, the second protective film, and the buffer layer may overlap in a direction parallel to the substrate.

The barrier layer may be an inorganic insulating layer.

The display device according to aspects of the present disclosure may further include a pad disposed in the pad area. The barrier layer may extend to the side of the pad.

The display device according to aspects of the present disclosure may further include a gate driving circuit including a plurality of gate-in-panel circuits GIPC configured to supply gate signals to the plurality of subpixels.

In the display device according to aspects of the present disclosure, the gate driving circuit may be disposed within the display area.

The display device according to aspects of the present disclosure may further include a plurality of pixel areas in which at least one subpixel among the plurality of subpixels is disposed, and a plurality of gate driving circuit areas in which at least one of the plurality of gate-in-panel circuits is disposed.

The display area may include a plurality of sub-display areas.

Each of the plurality of sub-display areas may include at least one of the plurality of pixel areas and at least one of the plurality of gate driving circuit areas.

Each of the plurality of gate driving circuit areas (i.e., the plurality of gate-in-panel circuits) may be disposed between two adjacent pixel areas among the plurality of pixel areas.

The display device according to aspects of the present disclosure may further include a first connection line and a second connection line electrically connecting two or more gate-in-panel circuits among the plurality of gate-in-panel circuits.

The display device according to aspects of the present disclosure may further include a light emitting device on the insulating layer, an encapsulation layer on the insulating layer, a plurality of sensor electrodes on the encapsulation layer, and a plurality of touch routing lines corresponding to the plurality of sensor electrodes,

The non-display area may include a first non-display area located outside the display area in a first direction and including the pad area, a second non-display area located outside the display area in a second direction different from the first direction, a third non-display area located outside the display area in a direction opposite to the first direction, and a fourth non-display area located outside the display area in a direction opposite to the second direction.

The plurality of touch routing lines may be not disposed in the second non-display area, the third non-display area, and the fourth non-display area, and at least a portion of the plurality of touch routing lines may extend across the display area to the pad area in the first non-display area.

A plurality of touch routing lines may extend along an outer sides of the second foreign matter protective layer, the first foreign matter protective layer, and the insulating layer in the first non-display area, and may be electrically connected to the touch pad disposed in the pad area.

The groove formed in the substrate may include a first inner side and a second inner side. The first inner side may be located closer to the display area than the second inner side, and at least one of the first inner side and the second inner side may have a plurality of steps.

A display device according to aspects of the present disclosure may include a substrate including a display area on which a plurality of subpixels are disposed, and a non-display area located outside the display area and including a pad area, an insulating layer disposed on the substrate, and a bank disposed on the insulating layer and having a plurality of openings.

The non-display area may include a first non-display area located outside the display area in a first direction and including a pad area, a second non-display area located outside the display area in a second direction different from the first direction, a third non-display area located outside the display area in a direction opposite to the first direction, and a fourth non-display area located outside the display area in the direction opposite to the second direction.

The display device according to aspects of the present disclosure may further include a groove which is not formed in at least a portion of the first non-display area including the pad area among the non-display areas, and is formed in the substrate in the form of a trench in remaining non-display area excluding the first non-display area among the non-display area.

The display device according to aspects of the present disclosure may further include a barrier layer extending from an upper portion of the bank to the groove.

The display device according to aspects of the present disclosure may further include a gate driving circuit including a plurality of gate-in-panel circuits configured to supply gate signals to the plurality of subpixels.

In the display device according to aspects of the present disclosure, the gate driving circuit may be disposed within the display area.

The display device according to aspects of the present disclosure may further include a light emitting device on the insulating layer, an encapsulation layer on the insulating layer, a plurality of sensor electrodes on the encapsulation layer, and a plurality of touch routing lines corresponding to the plurality of sensor electrodes.

The plurality of touch routing lines may be not disposed in the remaining non-display areas except the first non-display area including the pad area, and at least a portion of the plurality of touch routing lines may be disposed to extend across the display area to the pad area in the first non-display area.

The display device according to aspects of the present disclosure may further include a light emitting device on the insulating layer, a first protective film disposed on the light emitting device, a first foreign matter protective layer disposed on the first protective film, and a second protective film disposed on the first foreign matter protective layer.

The first protective film may include a first material protective film including a first material, and a second material protective film including a second material different from the first material.

According to aspects of the present disclosure, there may provide a display device with an extremely narrow bezel structure.

According to aspects of the present disclosure, there may provide a display device capable of implementing an extremely narrow bezel while preventing overflow of an organic layer included in an encapsulation layer to prevent moisture and oxygen from penetrating.

According to aspects of the present disclosure, there may provide a display device capable of implementing an extremely narrow bezel while effectively preventing moisture penetration.

According to aspects of the present disclosure, there may provide a display device including a gate-in-panel circuit structure which enables an extremely narrow bezel.

According to aspects of the present disclosure, there may provide a display device with a touch routing structure which enables an extremely narrow bezel.

According to aspects of the present disclosure, it is possible to reduce the weight of a display device by having an extremely narrow bezel structure.

The above description and the accompanying drawings provide an example of the technical idea of the present disclosure for illustrative purposes only. Various modifications, additions and substitutions to the described aspects will be readily apparent to those skilled in the art without departing from the spirit and scope of the present disclosure. In addition, the disclosed aspects are intended to illustrate the scope of the technical idea of the present disclosure. Thus, it is intended that the present disclosure covers the modifications and variations of the aspects provided they come within the scope of the appended claims and their equivalents.

What is claimed is:

1. A display device comprising:
a substrate including a display area on which a plurality of subpixels are arranged, a non-display area located outside the display area and including a pad area, and a groove disposed in the non-display area;
an insulating layer disposed on the substrate;
a bank disposed on the insulating layer and having a plurality of openings; and
a barrier layer extending from an upper portion of the bank to the groove.

2. The display device of claim 1, wherein the substrate includes a first substrate, a second substrate and a substrate intermediate layer disposed between the first substrate and the second substrate, and the groove is disposed in the second substrate.

3. The display device of claim 1, wherein the non-display area comprises:
a first non-display area located outside the display area in a first direction and including the pad area;
a second display area located outside the display area in a second direction different from the first direction;
a third non-display area located outside the display area in a direction opposite to the first direction; and
a fourth non-display area located outside the display area in a direction opposite to the second direction,
wherein the groove is formed in a form of a trench along the second non-display area, the third non-display area, and the fourth non-display area on the substrate, and is not formed in at least a portion of the first non-display area.

4. The display device of claim 1, wherein the barrier layer extends from the outermost upper portion of the bank to an inside of the groove along a side of the insulating layer.

5. The display device of claim 1, further comprising:
a plurality of anodes located on the insulating layer and each disposed in a plurality of emission areas;
a first common intermediate layer commonly located on the plurality of anodes;
a plurality of emission layers located on the first common intermediate layer and each disposed in the plurality of emission areas;
a second common intermediate layer commonly located on the plurality of emission layers; and
a cathode located on the second common intermediate layer,
wherein the first common intermediate layer, the second common intermediate layer, and the cathode are disposed on an inner side of the barrier layer, and are not disposed on an upper portion of the barrier layer.

6. The display device of claim 1, further comprising:
a cathode; and
a capping layer disposed on the cathode,
wherein the capping layer is disposed on an inner side of the barrier layer, and is not disposed on an upper portion of the barrier layer.

7. The display device of claim 5, further comprising:
a first protective film disposed on the cathode;
a first foreign matter protective layer disposed on the first protective film; and
a second protective film disposed on the first foreign matter protective layer,
wherein the first protective film includes a first material protective film including a first material, and a second material protective film including a second material different from the first material, and
wherein one of the first material protective film and the second material protective film has a thinner thickness than another.

8. The display device of claim 7, wherein an outermost portion of the first protective film is located on the upper portion or the inner side of the barrier layer.

9. The display device of claim 7, wherein the second protective layer includes a single layer.

10. The display device of claim 7, wherein the second protective film extends along sides of the first foreign matter protective layer and the insulating layer.

11. The display device of claim 7, further comprising:
a second foreign matter protective layer disposed on the second protective film; and
a buffer layer disposed on the second foreign matter protective layer.

12. The display device of claim 11, wherein the buffer layer extends along sides of the second foreign matter protective layer, the first foreign matter protective layer, and the insulating layer,
wherein at least one of the second protective film and the buffer layer is located inside the groove.

13. The display device of claim 11, wherein a side of the insulating layer, the barrier layer, the second protective film, and the buffer layer overlap in a direction parallel to the substrate.

14. The display device of claim 1, wherein the barrier layer includes an insulating material.

15. The display device of claim 1, further comprising a gate driving circuit including a plurality of gate-in-panel circuits configured to supply gate signals to the plurality of subpixels,
wherein the gate driving circuit is disposed within the display area.

16. The display device of claim 15, further comprising:
a plurality of pixel areas in which at least one subpixel among the plurality of subpixels is disposed; and
a plurality of gate driving circuit areas in which at least one of the plurality of gate-in-panel circuits is disposed,
wherein the display area includes a plurality of sub-display areas,
wherein each of the plurality of sub-display areas includes at least one of the plurality of pixel areas and at least one of the plurality of gate driving circuit areas.

17. The display device of claim 16, wherein each of the plurality of gate-in-panel circuits is disposed between two adjacent pixel areas among the plurality of pixel areas.

18. The display device of claim 16, further comprising a first connection line and a second connection line electrically connecting two or more gate-in-panel circuits among the plurality of gate-in-panel circuits.

19. The display device of claim 1, further comprising:
a light emitting device disposed on the insulating layer;
an encapsulation layer disposed on the insulating layer;
a plurality of sensor electrodes disposed on the encapsulation layer; and
a plurality of touch routing lines corresponding to the plurality of sensor electrodes,
wherein the non-display area comprises:
a first non-display area located outside the display area in a first direction and including the pad area;
a second non-display area located outside the display area in a second direction different from the first direction;
a third non-display area located outside the display area in a direction opposite to the first direction; and
a fourth non-display area located outside the display area in a direction opposite to the second direction,
wherein the plurality of touch routing lines are not disposed in the second non-display area, the third non-display area, and the fourth non-display area, and
wherein at least a portion of the plurality of touch routing lines extend across the display area to the pad area in the first non-display area.

20. The display device of claim 1, wherein the groove includes a first inner side and a second inner side,
wherein the first inner side is located closer to the display area than the second inner side, and
wherein at least one of the first inner side and the second inner side has a plurality of steps.

21. A display device comprising:
a substrate including a display area on which a plurality of subpixels are disposed, and a non-display area located outside the display area and including a pad area;
an insulating layer disposed on the substrate;
a bank disposed on the insulating layer and having a plurality of openings; and
a groove formed in the non-display area except for a portion of the non-display area.

22. The display device of claim 21, further comprising a barrier layer extending from an upper portion of the bank to the groove.

23. The display device of claim 21, further comprising a gate driving circuit including a plurality of gate-in-panel circuits configured to supply gate signals to the plurality of subpixels,
wherein the gate driving circuit is disposed within the display area.

24. The display device of claim 21, further comprising:
a light emitting device disposed on the insulating layer;
an encapsulation layer disposed on the insulating layer;
a plurality of sensor electrodes disposed on the encapsulation layer; and
a plurality of touch routing lines corresponding to the plurality of sensor electrodes,
wherein the plurality of touch routing lines are not disposed in the remaining non-display area,
wherein at least a portion of the plurality of touch routing lines is disposed to extend across the display area to the pad area in the first non-display area.

25. The display device of claim 21, further comprising:
a light emitting device disposed on the insulating layer;
a first protective film disposed on the light emitting device;
a first foreign matter protective layer disposed on the first protective film; and
a second protective film disposed on the first foreign matter protective layer,
wherein the first protective film includes a first material protective film including a first material, and a second material protective film including a second material different from the first material.

26. A display device comprising:
a substrate including a display area, a non-display area disposed outside the display area and a pad area disposed outside the non-display area, wherein the non-display area includes first, second, third and fourth non-display areas surrounding the display area;
an insulating layer disposed on the substrate;
a bank disposed on the insulating layer;
a trench formed in the substrate and extended along the second, third and fourth non-display areas that surround the display area except for the first non-display area facing the pad area;
a barrier layer disposed on the insulating layer and extending from the bank to the trench in the non-display area; and
an encapsulation layer disposed on the insulating layer.
